(19) United States
(12) Patent Application Publication
(10) Pub. No.: US 2018/0005685 A1
(43) Pub. Date: Jan. 4, 2018

(54) SEMICONDUCTOR DEVICE COMPRISING CHARGE PUMP CIRCUIT FOR GENERATING SUBSTRATE BIAS VOLTAGE

(71) Applicant: Renesas Electronics Corporation, Tokyo (JP)

(72) Inventor: Takumi HASEGAWA, Tokyo (JP)

(21) Appl. No.: 15/632,309

(22) Filed: Jun. 24, 2017

(30) Foreign Application Priority Data
Jun. 29, 2016 (JP) 2016-128856

(51) Int. Cl. G11C 11/4074; H01L 27/02; G05F 3/20; G11C 5/14; H03K 17/06; H02M 3/07

(52) U.S. Cl. CPC G11C 11/4074; H03K 17/063; H02M 3/073; G05F 3/205; G11C 5/145; H01L 27/0222

(57) ABSTRACT

In a semiconductor device, a substrate voltage generation circuit includes frequency-dividing/multiplying circuits for dividing or multiplying a frequency of a clock signal, and charge pump circuits configured to be operative in accordance with clock signals having divided or multiplied frequencies to generate substrate bias voltages. The frequency-dividing/multiplying circuits have a frequency-dividing/multiplying rate variable by a command issued from a processing circuit.

This nonprovisional application is based on Japanese Patent Application No. 2016-128856 filed on Jun. 29, 2016, with the Japan Patent Office, the entire contents of which are hereby incorporated by reference.

### BACKGROUND OF THE INVENTION

### Field of the Invention

The present disclosure relates to a semiconductor device and is used suitably for a MISFET which utilizes SOTB for example.

### Description of the Background Art

SOTB (Silicon ON Thin Buried oxide) is an SOI (Silicon ON Insulator) substrate structure in which an insulating layer is formed by a relatively thin buried oxide film (BOX: Buried Oxide) of approximately 10 nm. In a MISFET (a Metal Insulator Semiconductor Field Effect Transistor) which utilizes SOTB, a short channel effect can be suppressed by making small a thickness of a channel layer formed on a BOX layer. Furthermore, a threshold voltage is controllable by adjusting an impurity concentration of a substrate under the BOX layer. Accordingly, a variation of the threshold voltage can be suppressed by making low a concentration of the impurity of the channel layer (see Japanese Patent Laying-Open No. 2013-118317 regarding a MISFET on SOTB for example).

Furthermore, in the MISFET which utilizes SOTB, an individual transistor's threshold voltage can be adjusted by applying a voltage from the substrate utilizing a thin BOX layer. In that case, there is such an advantage that, by providing the thin BOX layer, a junction leakage current hardly flows between a source or a drain and a bulk substrate.

Although it does not use SOTB, Japanese Patent Laying-Open No. 2014-116014 discloses a technique to adjust a substrate bias voltage in accordance with a semiconductor device's internal temperature to control a MOS (Metal Oxide Semiconductor) transistor's leakage current.

Specifically, in the semiconductor device of this document, an adaptive substrate bias generator which generates a substrate voltage includes a look-up table and a voltage generator (see FIG. 6). The look-up table outputs a voltage code corresponding to a temperature code output from a temperature detector. The voltage generator generates a substrate bias voltage corresponding to the voltage code provided from the look-up table. For example, the voltage generator is composed of a voltage divider controlled by the voltage code.

Although Japanese Patent Laying-Open No. 2014-116014 indicates a function generator as another mounted example of the adaptive substrate bias generator (see FIG. 7), the document does not clarify its specific circuit configuration.

### SUMMARY OF THE INVENTION

In substrate bias control, it is necessary to generate a substrate bias voltage of a desired value efficiently. In this regard, Japanese Patent Laying-Open No. 2014-116014 hardly discloses specifically what method is used to generate a bias voltage. Although an example in configuration in accordance with a voltage divider is indicated as the only example, the voltage divider not only provides a large voltage loss but it is also necessary to supply a semiconductor device with a high voltage which serves as a source for voltage division, which invites an increased number of required power supply terminals.

Other issues and novel features will be apparent from the description in the specification and the accompanying drawings.

In a semiconductor device according to one embodiment, a substrate voltage generation circuit comprises: a frequency-dividing/multiplying circuit for dividing or multiplying a frequency of a clock signal; and a charge pump circuit configured to operate in accordance with the clock signal having the divided or multiplied frequency to generate a substrate bias voltage. The frequency-dividing/multiplying rate utilized in the frequency-dividing/multiplying circuit is variable by a command issued from a processing circuit.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a block diagram showing a configuration of a semiconductor device according to a first embodiment.

FIG. 2 is a block diagram showing a more detailed configuration of a substrate voltage generation circuit of FIG. 1.

FIG. 3 is a circuit diagram showing an example of a configuration of a frequency-dividing circuit of FIG. 2.

FIG. 4 is a circuit diagram showing an example of a configuration of a frequency-multiplying circuit of FIG. 2.

FIG. 5 is a circuit diagram showing an example of a configuration of a charge pump circuit of FIG. 2 for generating a PMOS substrate voltage.

FIG. 6 is a circuit diagram showing an example of a configuration of a charge pump circuit of FIG. 2 for generating an NMOS substrate voltage.

FIG. 7 shows a relationship between a frequency-dividing/multiplying rate and a substrate voltage generated by a charge pump circuit.

FIG. 8 is a cross section schematically showing a configuration of a MOS transistor formed on SOTB.

FIG. 9 is a block diagram showing a configuration of a semiconductor device according to a second embodiment.

FIG. 10 shows a relationship between a PMOS transistor's source-gate voltage and source-drain current.

FIG. 11 shows a relationship between a reverse substrate voltage and a CPU standby current.

FIG. 12 is a flowchart of a procedure followed to change a mode of operation in the semiconductor device of the second embodiment.

FIG. 13 is a flowchart of a procedure followed to change a mode of operation in a semiconductor device of a third embodiment.

FIG. 14 shows how a generated substrate voltage and a consumed current vary in a case where the frequency-dividing/multiplying rate utilized in the substrate voltage generation circuit is fixed.

FIG. 15 shows how a generated substrate voltage and a consumed current vary in a case where the frequency-dividing/multiplying rate is temporarily increased when the substrate voltage generation circuit starts to operate.

FIG. 16 is a block diagram showing a configuration of a semiconductor device according to a fourth embodiment.

FIG. 17 is a flowchart of a procedure followed to change a mode of operation in a semiconductor device of a fourth embodiment.

FIG. 18 shows a relationship between a reverse substrate voltage and a channel leakage current.

FIG. 19 shows a relationship between a reverse substrate voltage and a maximum operating frequency.

FIG. 20 shows a relationship between a CPU operating frequency and a CPU operating current for every one clock.

FIG. 21 is a block diagram showing a configuration of a semiconductor device according to a fifth embodiment.

FIG. 22 shows a relationship between a threshold voltage of PMOS and NMOS transistors of a SRAM, and a static noise margin limit and a write margin limit.

### DESCRIPTION OF THE PREFERRED EMBODIMENTS

In the following, each embodiment will specifically be described with reference to the drawings. In the figures, identical or corresponding components are identically denoted and will not be described repeatedly.

<Description of Terminology>

Initially, of the terms used in the present specification, those to which attention should be paid to will be described.

(1) Threshold voltage of MOS transistor: A threshold voltage of a MOS transistor is defined as an absolute value of a gate-source voltage (i.e., a potential difference between a potential Vg of a gate electrode and a potential Vs of a source electrode (i.e., Vg−Vs)) when the MOS transistor starts to be conducted. Accordingly, in this specification, a threshold voltage for an NMOS (Negative-channel MOS) transistor and a threshold voltage for a PMOS (Positive-channel MOS) transistor both have a positive value.

(2) Reverse substrate voltage: Reverse substrate voltage is defined as voltage between a substrate and a source electrode. Herein, a sign of a reverse substrate voltage is positive when a threshold voltage increases. Accordingly, for the NMOS transistor, when a substrate potential Vsub is lower than source potential Vs (Vsub<Vs), a threshold voltage is increased by a body effect, and accordingly, the reverse substrate voltage is defined as Vs−Vsub. For the PMOS transistor, when substrate potential Vsub is higher than source potential Vs (Vsub>Vs), a threshold voltage is increased by a body effect, and accordingly, the reverse substrate voltage is defined as Vsub−Vs. When the reverse substrate voltage is 0, normally, the NMOS transistor's substrate voltage is equal to a ground voltage VSS, and the PMOS transistor's substrate voltage is equal to a power supply voltage VDD.

(3) Frequency dividing/multiplying rate: When a frequency-dividing/multiplying rate is x, the frequency-dividing/multiplying circuit outputs a signal having a frequency that is x times as much as a frequency of an input clock signal. For a 1/m-frequency-dividing circuit, frequency-dividing/multiplying rate x is equal to 1/m. For an n-frequency-multiplying circuit, frequency-dividing/multiplying rate x is equal to n.

(4) Standby mode of operation of CPU (Central Processing Unit): A mode of operation of a CPU in which power lower than in a normal mode is consumed will be referred to as a standby mode of operation. In this specification, the standby mode of operation includes a case in which a frequency of a clock supplied to a CPU (Central Processing Unit) is changed to a low frequency, and a case in which supplying the CPU with the clock is stopped. In either case, power supplied to the CPU is not interrupted.

### First Embodiment

[Configuration of Semiconductor Device]

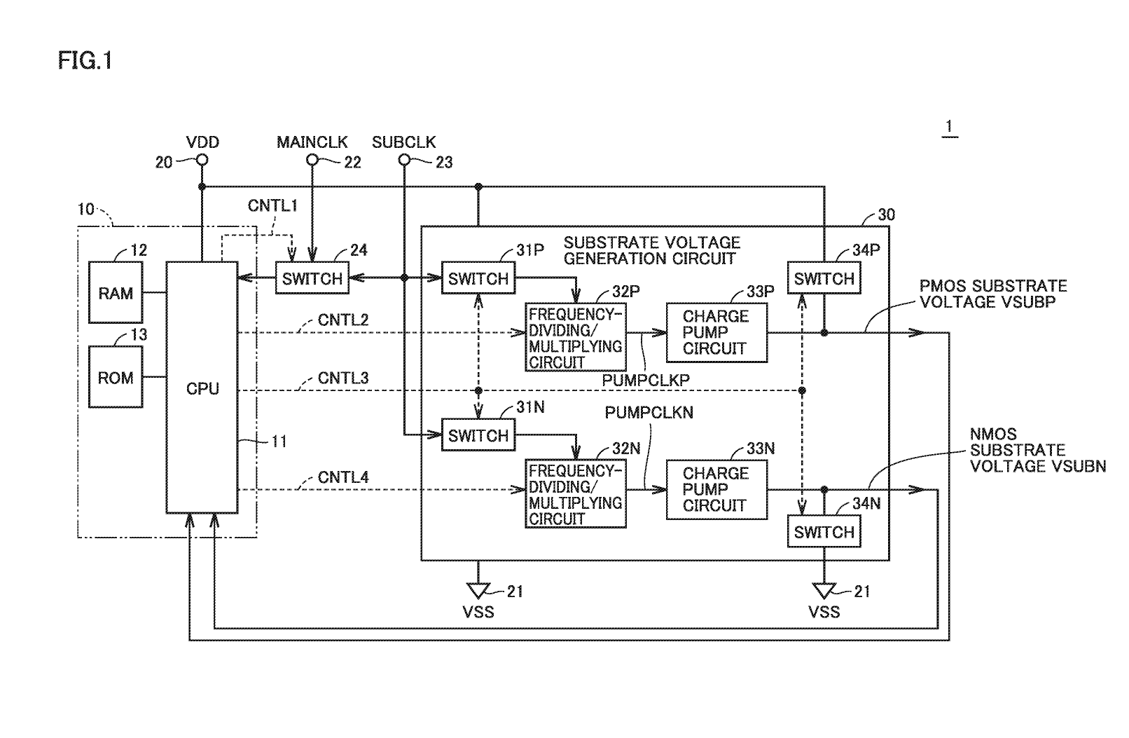

FIG. 1 is a block diagram showing a configuration of a semiconductor device according to a first embodiment. In FIG. 1, a line supplying power supply voltage VDD, a line supplying substrate bias voltages VSUBP and VSUBN, and a line supplying a clock signal (a main clock signal MAINCLK and a sub clock signal SUBCLK) are indicated by a solid line. Line supplying control signals CNTL1, CNTL2, CNTL3, and CNTL4 are indicated by a broken line. The other block diagrams also indicate a control signal line by a broken line.

With reference to FIG. 1, a semiconductor device 1 includes a power supply node 20, a ground node 21, a main clock node 22, a sub clock node 23, a microcomputer 10, a substrate voltage generation circuit 30, and a switch 24. Each of these elements is formed on a common semiconductor substrate (not shown).

Power supply node 20 receives power supply voltage VDD, and ground node 21 receives ground voltage VSS. Power supply voltage VDD may be supplied from outside of semiconductor device 1 or generated by a power supply circuit internal to semiconductor device 1.

Main clock node 22 is supplied with main clock signal MAINCLK and sub clock node 23 is supplied with sub clock signal SUBCLK. Main clock signal MAINCLK and sub clock signal SUBCLK may be provided from outside of semiconductor device 1, or generated in a clock circuit internal to semiconductor device 1 by utilizing an external quartz oscillator connected to semiconductor device 1. Alternatively, the signals may be generated by an on-chip oscillator internal to semiconductor device 1.

The frequency of sub clock signal SUBCLK is lower than the frequency of main clock signal MAINCLK. For example, main clock signal MAINCLK is used in a normal operation, whereas sub clock signal SUBCLK is used in a low power consumption mode. Furthermore, in semiconductor device 1 of this embodiment, a frequency-divided/multiplied signal whose frequency is a divided or multiplied value of a frequency of sub clock signal SUBCLK is supplied to a charge pump circuit of substrate voltage generation circuit 30.

Microcomputer 10 includes a CPU (Central Processing Unit) 11, a RAM (Random Access Memory) 12, a ROM (Read Only Memory) 13, and other peripheral circuits (not shown). ROM 13 stores a program for operating CPU 11. RAM 12 and ROM 13 are used as main memory of CPU 11. CPU 11 operates in accordance with a program stored in ROM 13 and performs a variety of operation processings, and also controls an operation of switch 24 and that of substrate voltage generation circuit 30.

Microcomputer 10 is shown as an example of a more general semiconductor integrated circuit. Semiconductor integrated circuit 10 may be composed of an ASIC (Application Specific Integrated Circuit) or an FPGA (Field-Programmable Gate Array) or the like. The semiconductor integrated circuit includes a processing circuit corresponding to CPU 11 (CPU 11 is an example of a processing circuit), and the processing circuit outputs control signals CNTL1, CNTL2, CNTL3, and CNTL4 for controlling switch 24 and substrate voltage generation circuit 30.

Switch 24 is a switch which operates in accordance with control signal CNTL1 received from CPU 11 to supply one of main clock signal MAINCLK and sub clock signal SUBCLK to CPU 11.

Substrate voltage generation circuit 30 operates in accordance with control signals CNTL2, CNTL3 and CNTL4 received from CPU 11 to generate substrate bias voltages VSUBP, VSUBN supplied to microcomputer 10 (in the present embodiment, CPU 11, in particular). The substrate bias voltages include substrate bias voltage VSUBP for a PMOSFET and substrate bias voltage VSUBN for an NMOSFET.

Specifically, Substrate voltage generation circuit 30 comprises a switch 31P, a frequency-dividing/multiplying circuit 32P, a charge pump circuit 33P, and a switch 34P as a configuration for generating substrate bias voltage VSUBP for a PMOSFET. Furthermore, substrate voltage generation circuit 30 comprises a switch 31N, a frequency-dividing/multiplying circuit 32N, a charge pump circuit 33N, and a switch 34N as a configuration for generating substrate bias voltage VSUBN for an NMOSFET.

Switches 31P and 31N are on/off switches which operate in accordance with control signal CNTL3 provided from CPU 11. Specifically, when control signal CNTL3 is in an active state, switch 31P supplies sub clock signal SUBCLK to frequency-dividing/multiplying circuit 32P, whereas when control signal CNTL3 is in an inactive state, switch 31P interrupts sub clock signal SUBCLK and does not supply it to frequency-dividing/multiplying circuit 32P. Similarly, when control signal CNTL3 is in the active state, switch 31N supplies sub clock signal SUBCLK to frequency-dividing/multiplying circuit 32N, whereas when control signal CNTL3 is in the inactive state, switch 31N interrupts sub clock signal SUBCLK and does not supply it to frequency-dividing/multiplying circuit 32N.

Frequency dividing/multiplying circuit 32P divides or multiplies a frequency of sub clock signal SUBCLK that is received via switch 31P to generate a clock signal PUMPCLKP for driving charge pump circuit 33P. Frequency dividing/multiplying circuit 32P has a frequency-dividing/multiplying rate controlled by control signal CNTL2. Similarly, frequency-dividing/multiplying circuit 32N divides or multiplies a frequency of sub clock signal SUBCLK that is received via switch 31N to generate a clock signal PUMPCLKN for driving charge pump circuit 33N. Frequency dividing/multiplying circuit 32N has a frequency-dividing/multiplying rate controlled by control signal CNTL4.

Charge pump circuit 33P boosts power supply voltage VDD in a positive direction to generate substrate bias voltage VSUBP for the PMOSFET. Accordingly, substrate bias voltage VSUBP generated is higher than power supply voltage VDD. Charge pump circuit 33N boosts ground voltage VSS in a negative direction (herein, boosting means increasing the voltage's absolute value) to generate substrate bias voltage VSUBP for the PMOSFET. Accordingly, substrate bias voltage VSUBN generated is lower than ground voltage VSS. In other words, when ground voltage VSS is 0 V, substrate bias voltage VSUBN is a negative voltage.

Switches 34P and 34N are on/off switches which operate in accordance with control signal CNTL3. When control signal CNTL3 is in the active state, switch 34P is in an off state, whereas when control signal CNTL3 is in the inactive state, switch 34P is in an on state to fix substrate bias voltage VSUBP for the PMOSFET to power supply voltage VDD. When control signal CNTL3 is in the active state, switch 34N is in the off state, whereas when control signal CNTL3 is in the inactive state, switch 34N is in the on state to fix substrate bias voltage VSUBN for the NMOSFET to ground voltage VSS.

Thus, when control signal CNTL3 is in the active state, substrate voltage generation circuit 30 is in an operating state to output as substrate bias voltages VSUBP, VSUBN the boost voltages generated as charge pump circuits 33P and 33N operate, whereas when control signal CNTL3 is in the inactive state, substrate voltage generation circuit 30 is in an non-operating state in which charge pump circuits 33P and 33N do not operate.

[Specific Configuration of Substrate Voltage Generation Circuit]

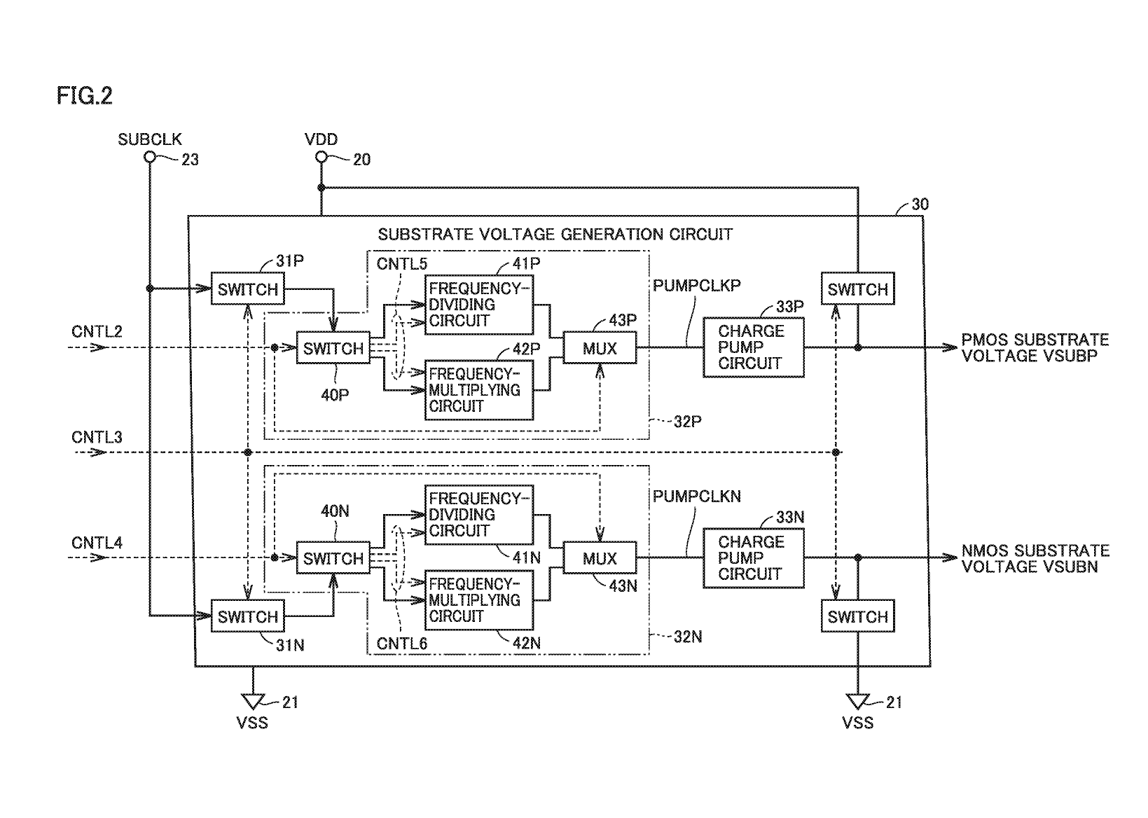

FIG. 2 is a block diagram showing a more detailed configuration of the substrate voltage generation circuit of FIG. 1. A more detailed configuration of frequency-dividing/multiplying circuits 32P and 32N of FIG. 1 is shown in FIG. 2. Of FIG. 2, any portion identical or corresponding to FIG. 1 will be identically denoted and will not be described redundantly.

With reference to FIG. 2, frequency-dividing/multiplying circuit 32P includes a switch circuit 40P, a frequency-dividing circuit 41P, a frequency-multiplying circuit 42P, and a multiplexer 43P (MUX). To reduce an operating current, as will be described hereinafter, frequency-dividing circuit 41P and frequency-multiplying circuit 42P are selectively operated. Specifically, when clock signal PUMPCLKP for a charge pump which has a lower frequency than sub clock signal SUBCLK is generated, frequency-dividing circuit 41P is alone operated and frequency-multiplying circuit 42P is stopped from operating. On the contrary, when clock signal PUMPCLKP for the charge pump which has a higher frequency than sub clock signal SUBCLK is generated, frequency-multiplying circuit 42P is alone operated and frequency-dividing circuit 41P is stopped from operating. Hereinafter, an operation of each component will be described.

When control signal CNTL2 indicates starting frequency-dividing circuit 41P to operate, and a frequency-dividing rate, switch circuit 40P supplies frequency-dividing circuit 41P with a control signal CNTL5 including information of a start operation command and the frequency-dividing rate and also supplies frequency-dividing circuit 41P with the sub clock signal received via switch 31P. In that case, switch circuit 40P transmits control signal CNTL5 including a stop operation command to frequency-multiplying circuit 42P and does not supply sub clock signal SUBCLK thereto. Thus, frequency-dividing circuit 41P starts operating and frequency-multiplying circuit 42P stops operating.

When control signal CNTL2 indicates starting frequency-multiplying circuit 42P to operate, and a frequency-multiplying rate, switch circuit 40P supplies frequency-multiplying circuit 42P with control signal CNTL5 including information of the start operation command and the frequency-multiplying rate and also supplies frequency-multiplying circuit 42P with the sub clock signal received via switch 31P. In that case, switch circuit 40P transmits control signal CNTL5 including the stop operation command to frequency-dividing circuit 41P and does not supply sub clock signal SUBCLK thereto. Thus, frequency-multiplying circuit 42P starts operating and frequency-dividing circuit 41P stops operating.

Multiplexer 43P operates in accordance with control signal CNTL2 to output sub clock signal SUBCLK output from frequency-dividing circuit 41P and having a divided frequency as clock signal PUMPCLKP for a charge pump circuit when frequency-dividing circuit 41P is in operation. Multiplexer 43P operates in accordance with control signal CNTL2 to output sub clock signal SUBCLK output from frequency-multiplying circuit 42P and having a multiplied frequency as clock signal PUMPCLKP for the charge pump circuit when frequency-multiplying circuit 42P is in operation.

Similarly, frequency-dividing/multiplying circuit 32N comprises a switch circuit 40N, a frequency-dividing circuit 41N, a frequency-multiplying circuit 42N, and a multiplexer 43N (MUX). These circuits operate similarly as described for frequency-dividing/multiplying circuit 32P for the PMOSFEET. Specifically, switch circuit 40P, frequency-dividing circuit 41P, frequency-multiplying circuit 42P, multiplexer 43P, clock signal PUMPCLKP for a charge pump, and control signals CNTL2 and CNTL5 may be replaced with switch circuit 40N, frequency-dividing circuit 41N, frequency-multiplying circuit 42N, multiplexer 43N, clock signal PUMPCLKN for a charge pump, and control signals CNTL4 and CNTL6, respectively. Accordingly, they will not specifically be described repeatedly.

[Example in Configuration of Frequency-Dividing Circuit]

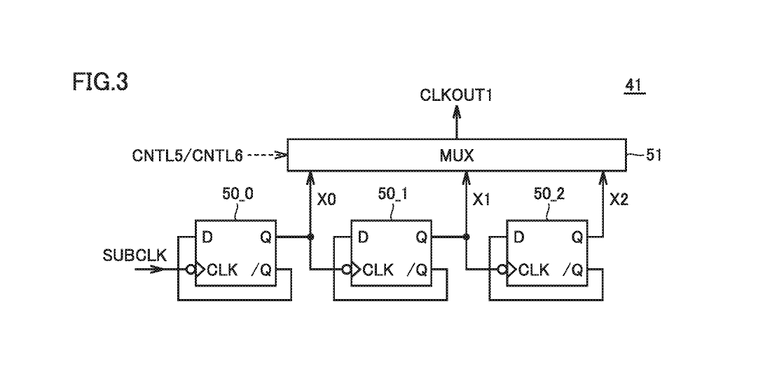

FIG. 3 is a circuit diagram showing an example of a configuration of the frequency-dividing circuit of FIG. 2. Frequency dividing circuits 41P and 41N of FIG. 2 are implemented by a frequency-dividing circuit 41 of a common configuration shown in FIG. 3 for example. Frequency dividing circuit 41 of FIG. 3 utilizes a counter circuit. Note that frequency-dividing circuit 41 which can be used in the present embodiment is not limited to the configuration of FIG. 3.

With reference to FIG. 3, frequency-dividing circuit 41 comprises a plurality of D-flip-flops 50_0, 50_1, 50_2 series-connected in multiple stages (indicated as a D-flip-flop 50 when collectively referred to), and a multiplexer 51 (MUX). While FIG. 3 shows D-flip-flop 50 series-connected in 3 stages by way of example for simplicity, in reality, D-flip-flop 50 is connected in more stages.

In D-flip-flop 50 of each stage, an inverted output signal/Q is input as an input signal D. Non-inverted output signal Q of D-flip-flop 50_i (where i=0, 1, 2, . . . ) of each stage is input to D-flip-flop 50_i+1 of the following stage as a clock signal CLK, and is further input to multiplexer 51 as an output signal Xi of each stage. Multiplexer 51 operates in accordance with control signal CNTL5/CNTL6 to output any one of output signals X0, X1, . . . as a clock signal CLKOUT1.

According to the above configuration, output signal Xi of an i-th stage D-flip-flop 50_i (where i=0, 1, 2, . . . ) has a frequency that is generated by dividing sub clock signal SUBCLK by an i-th power of 2. Accordingly, a frequency of clock signal CLKOUT1 to be output can be changed by selecting output signal Xi of D-flip-flop 50_i by multiplexer 51.

[Example in Configuration of Frequency-Multiplying Circuit]

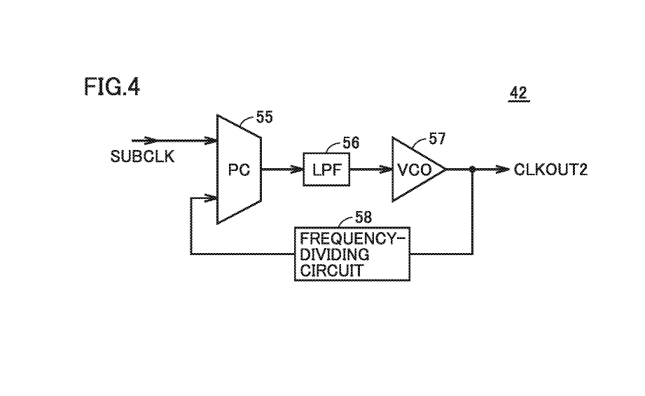

FIG. 4 is a circuit diagram showing an example in configuration of the frequency-multiplying circuit of FIG. 2. Frequency multiplying circuits 42P and 42N of FIG. 2 are implemented by a frequency-multiplying circuit 42 of a common configuration shown in FIG. 4 for example. Frequency multiplying circuit 42 of FIG. 4 utilizes a PLL (Phase Lock Loop) circuit. Note that frequency-multiplying circuit 42 which can be used in the present embodiment is not limited to the configuration of FIG. 4.

With reference to FIG. 4, frequency-multiplying circuit 42 comprises a phase comparator 55 (PC), a loop filter 56 (LPF), a voltage-controlled oscillator 57 (VCO), and a frequency-dividing circuit 58.

Phase comparator 55 detects a phase difference between sub clock signal SUBCLK (an input signal) and an output signal (a feedback signal) of frequency-dividing circuit 58. Loop filter 56 is a low pass filter which smoothes the output signal of phase comparator 55. Voltage-controlled oscillator 57 generates a clock signal CLKOUT2 of a frequency corresponding to an input voltage received from loop filter 56. Clock signal CLKOUT2 generated is output to charge pump circuit 33 as an output signal of frequency-multiplying circuit 42 to charge pump circuit 33 and also input to frequency-dividing circuit 58. Frequency dividing circuit 58 receives clock signal CLKOUT2, applies 1/m frequency division to clock signal CLKOUT2 (i.e., to generate a signal which has a frequency of 1/m of the frequency of clock signal CLKOUT2), and outputs the generated signal as the feedback signal to phase comparator 55. As frequency-dividing circuit 58, the configuration of the frequency-dividing circuit described with reference to FIG. 3 can be utilized for example.

According to the above configuration, clock signal CLKOUT2 output from frequency-multiplying circuit 42 has a frequency which is m times the frequency of sub clock signal SUBCLK input into frequency-multiplying circuit 42.

[Example in Configuration of Charge Pump Circuit]

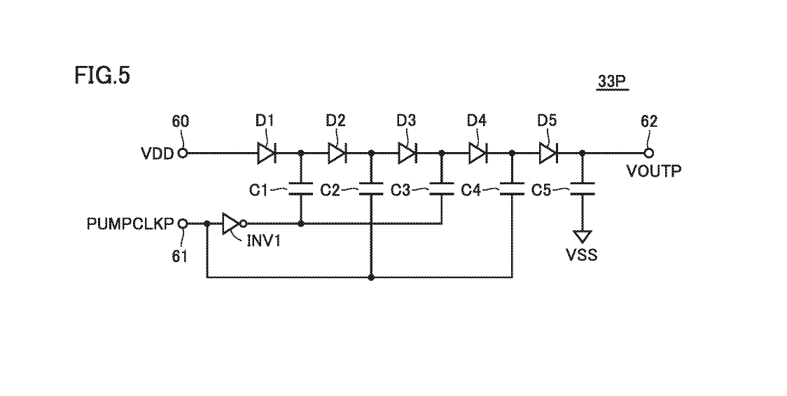

FIG. 5 is a circuit diagram showing an example of a configuration of a charge pump circuit of FIG. 2 for generating a PMOS substrate voltage. FIG. 5 shows charge pump circuit 33P, which is referred to as a Dickson type charge pump. Note that charge pump circuit 33P which can be used in the present embodiment is not limited to the configuration of FIG. 5.

With reference to FIG. 5, charge pump circuit 33P includes an input node 60, a signal node 61, an output node 62, a plurality of capacitors C1-C5, a plurality of diodes D1-D5, and an inverter INV1. The diode may be replaced with a diode-connected transistor.

While FIG. 5 shows five connected diodes D1-D5 by way of example for simplicity, in reality, more diodes are connected in series depending on a magnitude of a boost voltage required. The number of capacitors also increases as the number of diodes increases.

Initially, a configuration of charge pump circuit 33P will be described. Power supply voltage VDD is input to input node 60. Clock signal PUMPCLKP is input to signal node 61. Diodes D1-D5 are connected between input node 60 and output node 62 in a forward direction (i.e., such that input node 60 is on the side of an anode and output node 62 is on the side of a cathode) in series. Capacitors C1-C5 are associated with diodes D1-D5, respectively, and each capacitor has one end connected to a cathode of a diode associated therewith. Except for capacitor C5 of the last stage, odd-numbered capacitors C1 and C3 each have the other end connected to signal node 61 via inverter INV1, and even-numbered capacitors C2 and C4 each have the other end connected to signal node 61 directly. Capacitor C5 of the last stage has the other end connected to a ground node (ground voltage VSS).

An operation of charge pump circuit 33P of FIG. 5 will now be described. When clock signal PUMPCLKP has a high level (an H level), odd-numbered diodes D1, D3, and D5 become an ON state, and even-numbered diodes D2 and D4 become an OFF state. Thus, capacitor C1 is provided with a positive charge from input node 60, a positive charge stored in capacitor C2 is transferred to capacitor C3, and a positive charge stored in capacitor C4 is transferred to capacitor C5. In contrast, when clock signal PUMPCLKP has a low level (an L level), even-numbered diodes D2 and D4 become the ON state, and odd-numbered diodes D1, D3 and D5 become the OFF state. Thus, a positive charge stored in capacitor C1 is transferred to capacitor C2, and a positive charge stored in capacitor C3 is transferred to capacitor C4. Thus, in response to clock signal PUMPCLKP, capacitors C1-C5 have their positive charges sequentially transferred. As a result, a capacitor of a latter stage is charged with an increased voltage, and as a result, a positive boost voltage VOUTP which is the same polarity as power supply voltage VDD is charged to capacitor C5.

As is apparent from the above operation, the larger the number of capacitors connected is, the larger a finally reachable, positive boost voltage is (i.e., a higher voltage is reached). Furthermore, the higher the frequency of clock signal PUMPCLKP is, the faster a positive charge is transferred and hence a proportion of a current which leaks from a capacitor and a diode decreases, and accordingly, a finally reachable, positive boost voltage becomes large.

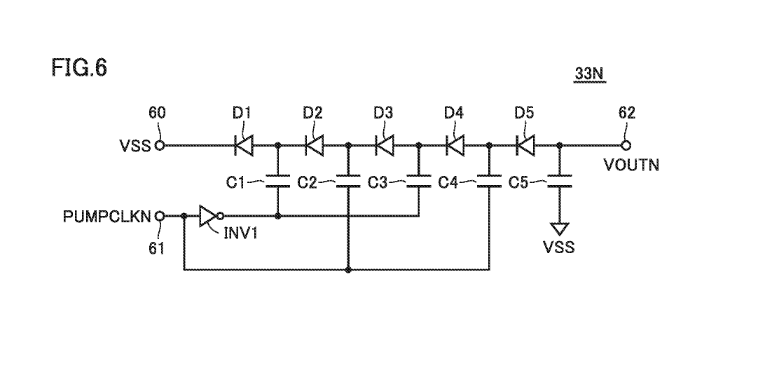

FIG. 6 is a circuit diagram showing an example of a configuration of a charge pump circuit of FIG. 2 for generating an NMOS substrate voltage.

FIG. 6 shows charge pump circuit 33N, which is different from the charge pump of FIG. 5 in that diodes D1-D5 are opposite in polarity (i.e., input node 60 is on the side of a cathode, and output node 62 is on the side of an anode), and that input node 60 does not receive power supply voltage VDD and instead receives ground voltage VSS. The remainder in configuration shown in FIG. 6 is similar to that of the case of FIG. 5, and accordingly, identical or corresponding components are identically denoted and will not be described repeatedly. Hereinafter, an operation of charge pump circuit 33N of FIG. 6 will be described.

When clock signal PUMPCLKN is the H level, odd-numbered diodes D1, D3, and D5 become the OFF state, and even-numbered diodes D2 and D4 become the ON state. Thus, a positive charge stored in capacitor C2 is transferred to capacitor C1, and a positive charge stored in capacitor C4 is transferred to capacitor C3. In contrast, when clock signal PUMPCLKN is the L level, even-numbered diodes D2 and D4 become the OFF state, and odd-numbered diodes D1, D3, and D5 become the ON state. Thus, a positive charge stored in capacitor C1 is drawn therefrom to input node 60, a positive charge stored in capacitor C3 is transferred to capacitor C2, and a positive charge stored in capacitor C5 is transferred to capacitor C4. Thus, in response to clock signal PUMPCLKN, capacitors C1-C5 have electrical charges sequentially transferred. As a result, a capacitor of a latter stage is charged with a lower voltage, and as a result, a negative boost voltage VOUTN which is opposite in polarity to power supply voltage VDD is charged to capacitor C5.

As is apparent from the above operation, the larger the number of capacitors connected is, the larger a finally reachable, negative boost voltage is (i.e., a lower voltage is reached). Furthermore, the higher the frequency of clock signal PUMPCLKN is, the faster an electrical charge is transferred and hence a proportion of a current which leaks from a capacitor and a diode decreases, and accordingly, a finally reachable, negative boost voltage becomes large.

[Operation of Substrate Voltage Generation Circuit]

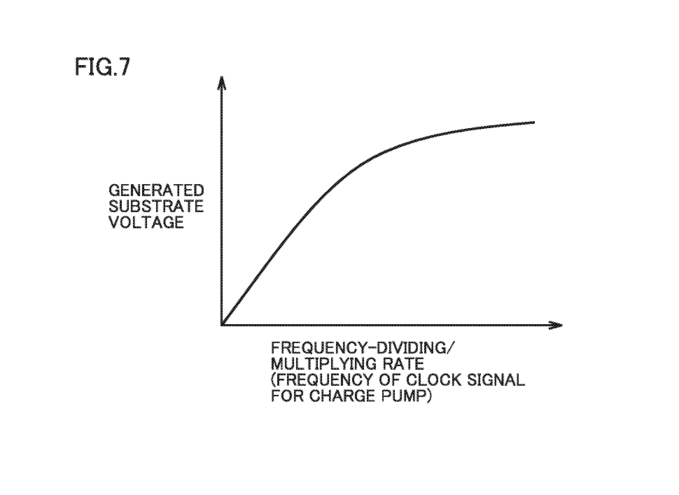

FIG. 7 shows a relationship between a frequency-dividing/multiplying rate and a substrate voltage generated by a charge pump circuit. In FIG. 7, the axis of abscissa represents a frequency-dividing/multiplying rate utilized in frequency-dividing/multiplying circuit 32, and the axis of ordinate represents a voltage generated by the charge pump circuit in absolute value. Note that since clock signals PUMPCLKP and PUMPCLKN of charge pump circuits 33P and 33N are generated by frequency-dividing/multiplying circuits 32P and 32N, the frequency-dividing/multiplying rate is proportional to the frequencies of clock signals PUMPCLKP and PUMPCLKN.

Voltages VOUTP and VOUTN generated by charge pump circuits 33P and 33N are determined by a balance of an amount of an electric charge supplied to each capacitor of charge pump circuits 33P and 33N and an amount of the electric charge that leaks to a ground node. Accordingly, by increasing a frequency-dividing/multiplying rate, the frequencies of clock signals PUMPCLKP and PUMPCLKN input to charge pump circuits 33P and 33 can be increased to increase an amount of electric charge supplied to each capacitor of charge pump circuits 33P and 33N per unit time and consequently increase a generated substrate bias voltage's absolute value. However, as the frequency-dividing/multiplying rate increases, a rate at which the absolute values of voltages VOUTP and VOUTN increase tends to be saturated.

In an actual circuit operation, a relationship between the frequency-dividing/multiplying rate and voltages VOUTP and VOUTN generated by charge pump circuits 33P and 33N is measured previously, and stored in ROM 13 in the form of a table or a parameter of an experimental formula is stored in ROM 13. CPU 11 determines a frequency-dividing/multiplying rate corresponding to a desired substrate voltage by referring to the table or in accordance with the experimental formula, and outputs the determined frequency-dividing/multiplying rate to frequency-dividing/multiplying circuits 32P and 32N as control signals CNTL2 and CNTL4, respectively.

[Configuration of MOSFET Formed on SOTB]

Hereinafter, a MOSFET (also referred to as a MOS transistor) on SOTB which is a configuration of a transistor suitable for substrate bias control of the present embodiment will be described. In the following description, a gate insulating film is not limited to silicon oxide and may be of a different material. When using a gate insulating film of the different material, the transistor will be referred to as MISFET rather than MOSFET.

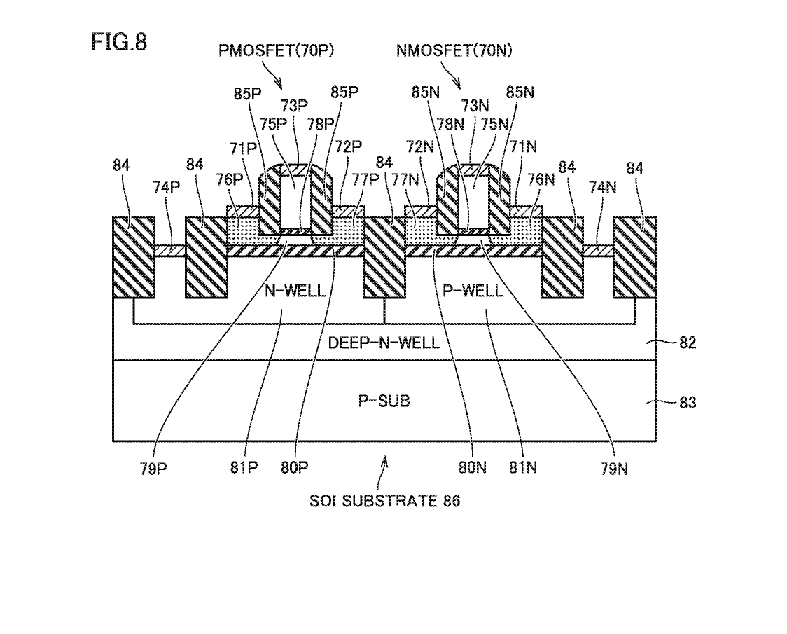

FIG. 8 is a cross section schematically showing a configuration of the MOS transistor formed on SOTB. An example of a cross-sectional configuration of a PMOSFET (70P) and an NMOSFET (70N) which were formed on an SOI substrate is shown by FIG. 8.

An SOI substrate 86 includes BOX layers 80P and 80N formed on a main surface of a P type silicon substrate (P-SUB) 83, and an SOI layer which is a monocrystalline silicon layer deposited on BOX layers 80P and 80N. The SOI layer is utilized to form channel regions 79P and 79N and impurity regions 76P, 77P, 76N, and 77N. Furthermore, at a region of P type silicon substrate 83 closer to the main surface, a deep N type well (a Deep-N-Well) 82 for element isolation is formed, and at an upper portion of deep N type well 82, an N type well (N-Well) 81P and a P type well (P-well) 81N are formed.

PMOSFET (70P) includes a channel region 79P formed on BOX layer 80P, impurity regions 76P and 77P formed on BOX layer 80P with the channel region interposed therebetween (i.e., a drain region 76P and a source region 77P), and a gate layer 75P formed on a surface of channel region 79P with a gate insulating film 78P interposed. Gate layer 75P is formed of doped polycrystalline silicon for example. A sidewall 85P which is an insulating film is formed to cover a sidewall of gate layer 75P. Impurity regions 76P and 77P and gate layer 75P have surfaces with metal electrodes 71P, 72P, and 73P (i.e., a drain electrode 71P, a source electrode 72P, a gate electrode 73P) formed thereon, respectively.

Similarly, NMOSFET (70N) includes a channel region 79N formed on BOX layer 80N, impurity regions 76N and 77N formed on BOX layer 80N with the channel region interposed therebetween (a source region 76N and a drain region 77N), and a gate layer 75N formed on a surface of channel region 79N with a gate insulating film 78N interposed. Gate layer 75N is formed of doped polycrystalline silicon, for example. A sidewall 85N which is an insulating film is formed to cover a sidewall of gate layer 75N. Impurity regions 76N and 77N and gate layer 75N have surfaces with metal electrodes 71N, 72N, and 73N (i.e., a source electrode 71N, a drain electrode 72N, a gate electrode 73N) formed thereon, respectively.

On a surface of N type well 81P, a substrate electrode 74P is provided for applying a substrate bias voltage to PMOSFET (70P) via BOX layer 80P. Similarly, on a surface of P type well 81N, a substrate electrode 74N is provided for applying a substrate bias voltage to NMOSFET (70N) via BOX layer 80N.

In the SOI substrate, furthermore, in order to electrically separate substrate electrodes 74P and 74N, PMOSFET (70P), and NMOSFET (70N), an STI (Shallow Trench Isolation) 84 is formed.

The device structure of FIG. 8 can be produced using a known method (see Japanese Patent Laying-Open No. 2013-118317 for example). Hereinafter, a device production method will be described briefly.

(1) STI 84 is initially formed in the SOI substrate. STI 84 is formed for example by using a photoresist as a mask to form a trench by etching, and burying an insulating film such as silicon oxide in the formed trench.

(2) Subsequently, deep N type well 82, N type well 81P, and P type well 81N are formed by ion implantation.

(3) Subsequently, a portion of the SOI layer and BOX layers 80P and 80N at which substrate electrodes 74P and 74N are formed is removed.

(4) Subsequently, PMOSFET (70P) and NMOSFET (70N) are formed. Specifically, this is done by following the following procedure:

(4.1) Gate insulating films 78P and 78N are initially formed on an entire surface of the SOI layer for example by thermal oxidation. And gate layers 75P and 75N are formed on entire surfaces of gate insulating films 78P and 78N.

(4.2) Subsequently, gate insulating films 78P and 78N and gate layers 75P and 75N are processed into a desired shape by photolithography and etching.

(4.3) Subsequently, after an insulating film such as silicon oxide is deposited on an entire surface, anisotropic etching is performed to form sidewalls 85P and 85N on sidewalls of gate layers 75P and 75N.

(4.4) Subsequently, source regions 77P and 76N and drain regions 76P and 77N are formed by selectively epitaxially growing monocrystalline silicon at a portion having the SOI layer exposed. A P type impurity is implanted in source region 77P and drain region 76P formed for PMOSFET (70P) and an N type impurity is implanted in source region 76N and drain region 77N formed for NMOSFET (70N).

(5) Subsequently, the device structure of FIG. 8 is completed by forming metal electrodes 71P-74P and 71N-74N. Note that before metal electrodes 71P-74P, 71N-74N are formed, a metal silicide layer may previously be formed on a surface of a semiconductor layer to be provided with the metal electrodes.

[Effect]

Thus, according to the semiconductor device of the first embodiment by changing a frequency of a clock signal that is supplied to a charge pump circuit by a frequency-dividing/multiplying circuit, a desired substrate bias voltage can be generated. This method of generating a substrate bias voltage can generate a substrate bias voltage with a smaller loss and more efficiently than the method of Japanese Patent Laying-Open No. 2014-116014 using a voltage divider.

Furthermore, the above described substrate bias control can be suitably used for a MOSFET using a SOTB substrate. In that case, there is such an advantage that as the thin BOX layer is provided, a junction leakage current hardly flows between a source or a drain and a bulk substrate.

### Second Embodiment

[Configuration of Semiconductor Device]

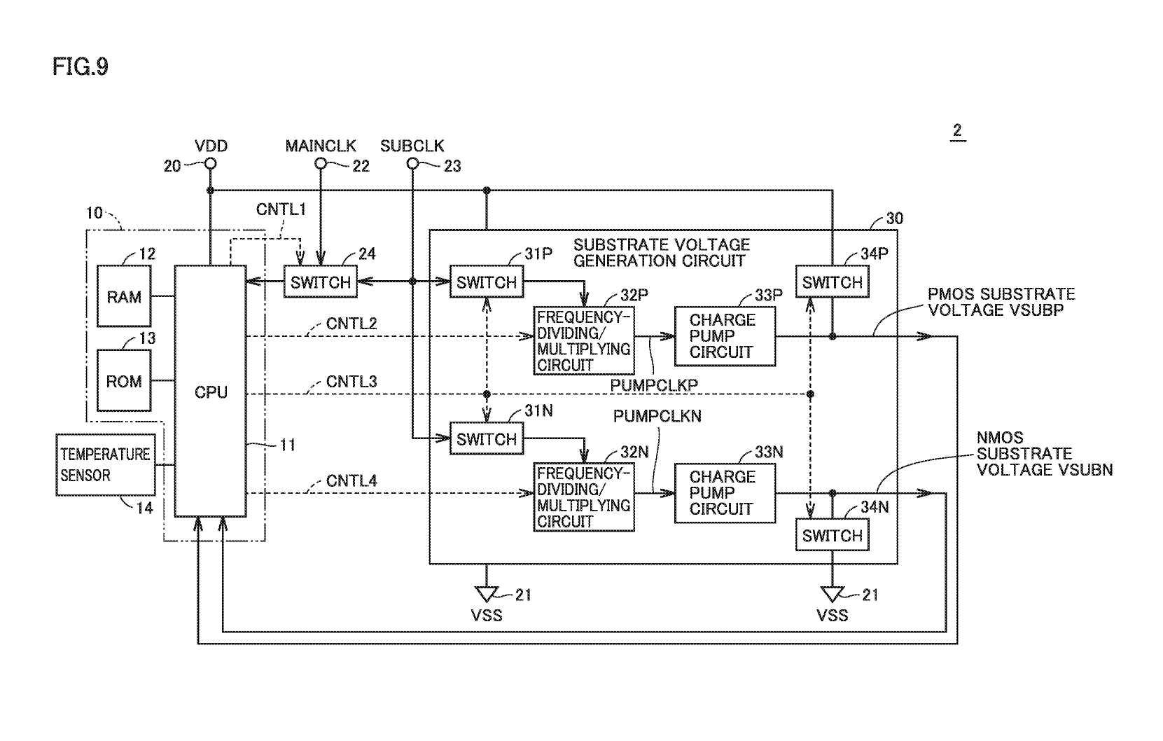

FIG. 9 is a block diagram showing a configuration of a semiconductor device according to a second embodiment. A semiconductor device 2 according to the second embodiment is different from semiconductor device 1 of the first embodiment in that the former further comprises a temperature sensor 14 provided on a semiconductor substrate. In order to sense a temperature of the substrate at a region in which CPU 11 is provided, temperature sensor 14 is provided preferably within or adjacent to that region. Although temperature sensor 14 is not particularly limited, for example it can be a thermistor or utilize PN junction's temperature dependency.

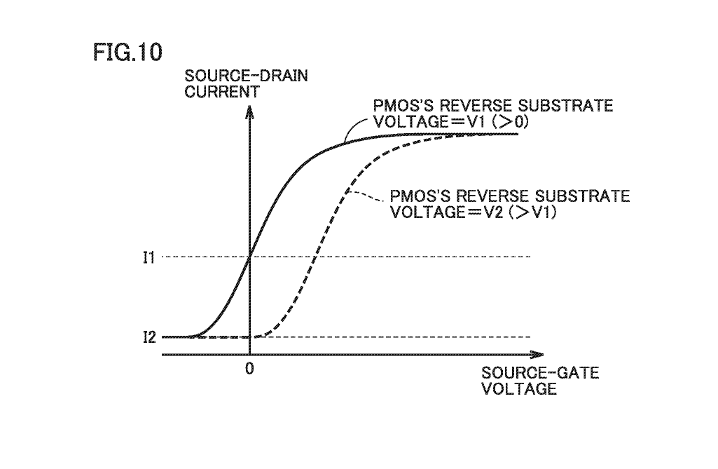

CPU 11 operates in accordance with a program to change a frequency-dividing/multiplying rate so as to provide an optimal substrate bias voltage based on a sensed value of temperature sensor 14. A specific substrate bias control method will be described later with reference to FIG. 10 to FIG. 12.

The remainder in FIG. 9 is similar to that described for the first embodiment with reference to FIG. 1 etc., and accordingly, identical or corresponding components are identically denoted and will not be described repeatedly.

[Reduction of Standby Current]

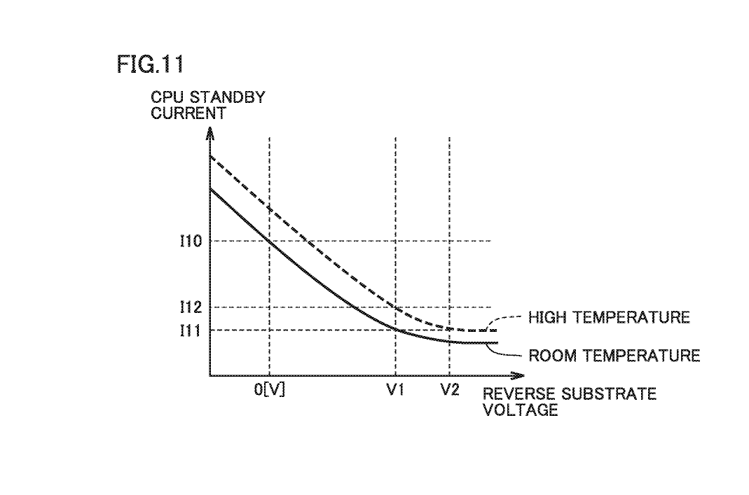

By adjusting a substrate bias voltage, a current consumed when the CPU is in a standby mode of operation (i.e., a standby current) can be reduced. This is because, by adjusting a substrate bias voltage, a threshold voltage can be increased and thereby a channel leakage current (also referred to as an off-state leakage current or a subthreshold leakage current) can be reduced. In the standby mode of operation, it is preferable to further adjust a substrate bias voltage depending on the substrate's temperature sensed by temperature sensor 14. Hereinafter, this will more specifically be described with reference to FIG. 10 and FIG. 11.

FIG. 10 shows a relationship between a PMOS transistor's source-gate voltage and source-drain current. With reference to FIG. 10, the source-gate voltage is a value of a source potential minus a gate potential. The source-drain current represents a current flowing in a direction from a source electrode to a drain electrode. A solid curved line represents a relationship in magnitude between the PMOS transistor's source-drain current and source-gate voltage for a reverse substrate voltage of V1 (a positive value). A broken curved line represents a relationship in magnitude between the PMOS transistor's source-drain current and source-gate voltage for a reverse substrate voltage of V2 larger than V1.

As shown in FIG. 10, in the case of the PMOS transistor, when the reverse substrate voltage is increased from V1 to V2 (the substrate bias voltage becomes further larger than the source voltage), the threshold voltage will increase, and accordingly, the source-drain current when the source-gate voltage is 0 V (i.e., a channel leakage current) decreases from I1 to I2.

In the case of an NMOS transistor also, a similar effect can be obtained by substrate bias control. Specifically, when the reverse substrate voltage is increased from V1 to V2 (the substrate bias voltage becomes further smaller than the source voltage), the drain-source current when the gate-source voltage is 0 V (i.e., a channel leakage current) can be reduced from I1 to I2.

Thus, by controlling a MOS transistor's substrate bias voltage, a channel leakage current can be reduced, and as a result, the CPU's standby current can be reduced.

FIG. 11 shows a relationship between a reverse substrate voltage and a CPU standby current. In FIG. 11, a solid line represents a relationship of a reverse substrate voltage and a CPU standby current when the substrate's temperature is equal to a room temperature, and a broken line represents such a relationship when the substrate's temperature is higher than the room temperature.

When the substrate's temperature is the room temperature and a mode is shifted to the standby mode of operation (i.e., supplying a clock is stopped) with the reverse substrate voltage remaining at 0 V, which is the same as in a normal operation, a standby current I10 flows through the CPU. At the time, by providing reverse substrate voltage V1, the standby current can be reduced from I10 to I11.

Then, when the substrate's temperature becomes a higher temperature than the room temperature, applying reverse substrate voltage V1 does not cause the standby current to be I11 but to increase it to I12 which is a value larger than I11. Accordingly, CPU 11 follows a program to increase a command value of a frequency-dividing/multiplying rate applied to frequency-dividing/multiplying circuits 32P and 32N in response to a sensed value of temperature sensor 14 such that a reverse substrate voltage supplied from substrate voltage generation circuit 30 is increased to V2. As a result, the standby current can be reduced to V11 which is the same as that for the room temperature.

Thus, by adjusting a frequency-dividing/multiplying rate depending on a sensed value of temperature sensor 14, a reverse substrate voltage is changed and, as a result, a standby current's temperature dependency can be reduced.

[Procedure to Shift Between Active Mode of Operation and Standby Mode of Operation]

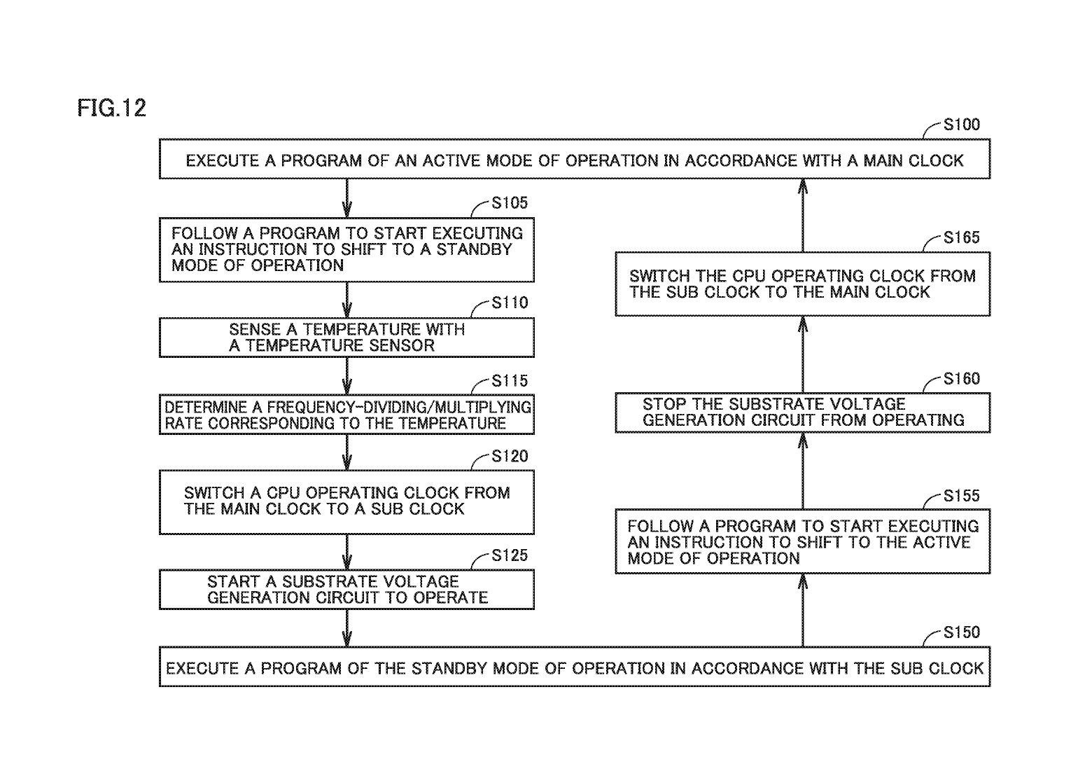

FIG. 12 is a flowchart of a procedure followed to change a mode of operation in the semiconductor device of the second embodiment. In the following description, a mode of operation when the CPU is in a normal state of operation will be referred to as an active mode of operation.

With reference to FIG. 9 and FIG. 12, CPU 11 operates in accordance with a program stored in ROM 13 to switch from the active mode of operation (i.e., when a normal operation is performed) to a standby mode of operation (i.e., when a low power consumption operation is performed), and vice versa. Hereinafter, a procedure to switch a mode of operation will specifically be described.

When the program is started, CPU 11 controls switch 24 by control signal CNTL1 to receive fast main clock signal MAINCLK. At the time, CPU 11 is executing a program of the active mode of operation in accordance with fast main clock signal MAINCLK (step S100).

Subsequently, CPU 11 follows a program to start executing an instruction to shift to the standby mode of operation (step S105). Initially, CPU 11 senses the substrate's temperature with temperature sensor 14 (step S110).

Subsequently, CPU 11 determines a frequency-dividing/multiplying rate for sub clock signal SUBCLK corresponding to the substrate's sensed temperature (step S115). CPU 11 sets a frequency-dividing/multiplying rate utilized in frequency-dividing/multiplying circuits 32P and 32N by control signals CNTL2 and CNTL4 to a value determined in accordance with the substrate's temperature.

Note that the higher the substrate's temperature is, the larger value the frequency-dividing/multiplying rate is set to. This allows clock signals PUMPCLKP and PUMPCLKN for charge pump circuits 33P and 33N to have a higher frequency, and charge pump circuits 33P and 33N to generate a substrate bias voltage having an increased absolute value (or provides a larger reverse substrate voltage). As a result, an increase of a channel leakage current of the MOS transistor accompanying an increase of the substrate's temperature (and hence an increase of a standby current of the CPU) can be suppressed.

Subsequently, CPU 11 switches switch 24 by control signal CNTL1 to receive sub clock signal SUBCLK instead of main clock signal MAINCLK (Step S120). Furthermore, CPU 11 activates control signal CNTL3 to start substrate voltage generation circuit 30 to operate (step S125). This completes shifting the active mode of operation to the standby mode of operation. Subsequently, CPU 11 executes a program of the standby mode of operation in accordance with slow sub clock signal SUBCLK (step S150).

While CPU 11 is executing the program of the standby mode of operation (step S150), CPU 11 follows a program to start executing an instruction to shift to the active mode of operation for the sake of illustration (step S155).

Initially, CPU 11 inactivates control signal CNTL3 to stop substrate voltage generation circuit 30 from operating (step S160). In that case, switch 34P is switched to provide power supply voltage VDD as substrate bias voltage VSUBP for PMOS. Switch 34N is switched to provide ground voltage VSS as substrate bias voltage VSUBN for NMOS.

Subsequently, CPU 11 switches switch 24 by control signal CNTL1 to receive main clock signal MAINCLK instead of sub clock signal SUBCLK (step S165). Subsequently, CPU 11 executes a program of the active mode of operation in accordance with fast main clock signal MAINCLK (step S100).

[Effect]

Thus, According to semiconductor device 2 of the second embodiment, a frequency-dividing/multiplying rate utilized in frequency-dividing/multiplying circuits 32P and 32N can be adjusted in accordance with a sensed value of temperature sensor 14 to adjust in accordance with the substrate's temperature a frequency of clock signals PUMPCLKP and PUMPCLKN supplied to charge pump circuits 33P and 33N. Thus, substrate bias voltages VSUBP and VSUBN generated by substrate voltage generation circuit 30 are adjusted in accordance with the substrate's temperature, and individual transistors' channel leakage currents (and hence the CPU's standby current) can be suppressed to the same degree regardless of the substrate's temperature.

### Third Embodiment

In a semiconductor device of a third embodiment, when substrate voltage generation circuit 30 is started, a frequency-dividing/multiplying rate is temporarily set to be a higher value to reduce a rising time of substrate voltage generation circuit 30.

Herein, the configuration of the semiconductor device of the third embodiment is identical to what has been described in the second embodiment described with reference to FIG. 9 and accordingly, will not be described repeatedly.

[Procedure to Shift Between Active Mode of Operation and Standby Mode of Operation]

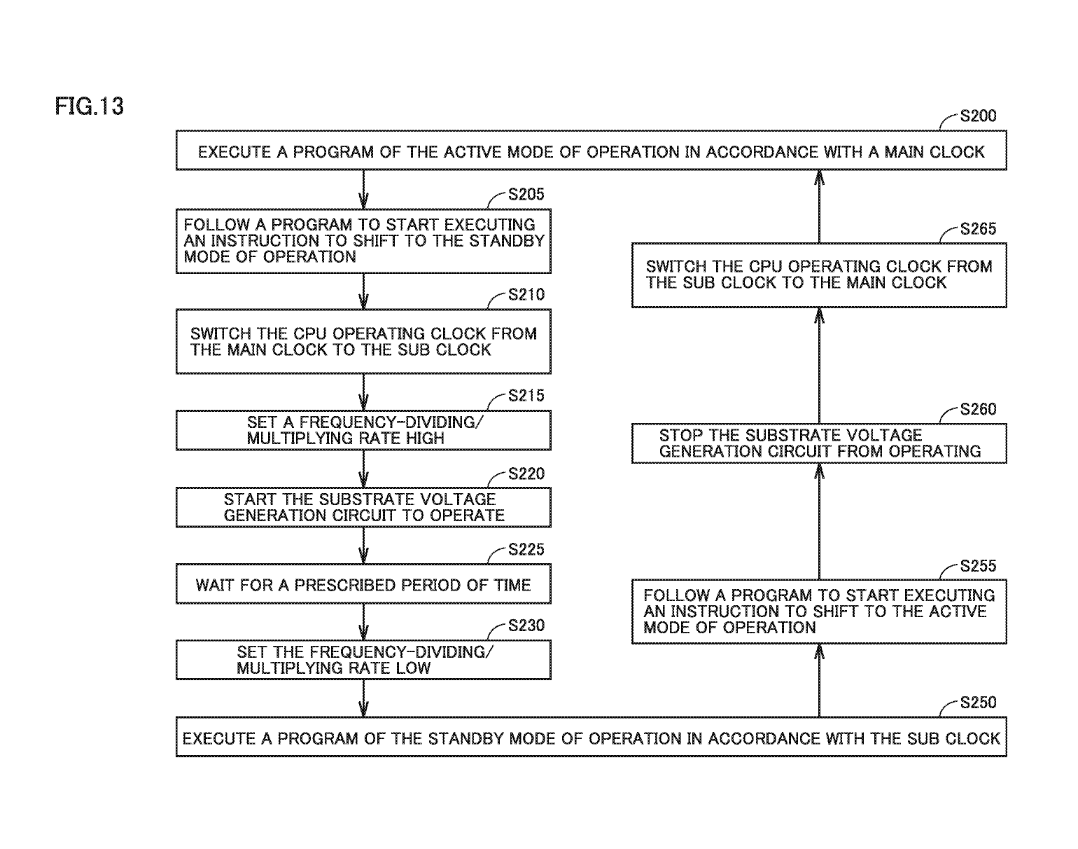

FIG. 13 is a flowchart of a procedure followed to change a mode of operation in the semiconductor device of the third embodiment.

With reference to FIG. 9 and FIG. 13, when a program is started, CPU 11 controls switch 24 by control signal CNTL1 to receive fast main clock signal MAINCLK. At the time, CPU 11 is executing a program of the active mode of operation in accordance with fast main clock signal MAINCLK (step S200).

Subsequently, CPU 11 follows a program to start executing an instruction to shift to the standby mode of operation (step S205). Initially, CPU 11 switches switch 24 by control signal CNTL1 to receive sub clock signal SUBCLK instead of main clock signal MAINCLK (Step S210).

Subsequently, CPU 11 sets a frequency-dividing/multiplying rate utilized in frequency-dividing/multiplying circuits 32P and 32N by control signals CNTL2 and CNTL4 to a value higher than when substrate voltage generation circuit 30 regularly operates (Step S215). When a frequency-dividing/multiplying rate is set based on a sensed value of temperature sensor 14, as has been described in the second embodiment, CPU 11 sets the frequency-dividing/multiplying rate to a value higher than a value corresponding to the sensed value of temperature sensor 14.

Subsequently, CPU 11 activates control signal CNTL3 to start substrate voltage generation circuit 30 to operate (step S220).

Subsequently, after a prescribed waiting time has elapsed (step S225) (i.e., after substrate bias voltages VSUBP and VSUBN output from substrate voltage generation circuit 30 have been stabilized), CPU 11 returns the frequency-dividing/multiplying rate to a value assumed when substrate voltage generation circuit 30 regularly operates (step S230). When a frequency-dividing/multiplying rate is set based on a sensed value of temperature sensor 14, as has been described in the second embodiment, CPU 11 returns the frequency-dividing/multiplying rate to a value corresponding to the sensed value of temperature sensor 14. This completes shifting the active mode of operation to the standby mode of operation. Subsequently, CPU 11 executes a program of the standby mode of operation in accordance with slow sub clock signal SUBCLK (step S250).

A procedure followed to sift the standby mode of operation to the active mode of operation is identical to that described with reference to FIG. 12, and accordingly, will briefly be described below.

When CPU 11 follows a program to start executing an instruction to shift to the active mode of operation (step S255), CPU 11 initially inactivates control signal CNTL3 to stop substrate voltage generation circuit 30 from operating (step S260). Subsequently, CPU 11 switches switch 24 by control signal CNTL1 to receive main clock signal MAINCLK instead of sub clock signal SUBCLK (Step S265). Subsequently, CPU 11 executes a program of the active mode of operation in accordance with fast main clock signal MAINCLK (step S200).

[Effect]

Hereinafter, an effect of temporarily increasing a frequency-dividing/multiplying rate when substrate voltage generation circuit 30 starts to operate, as has been described above, will be described in comparison with a comparative example.

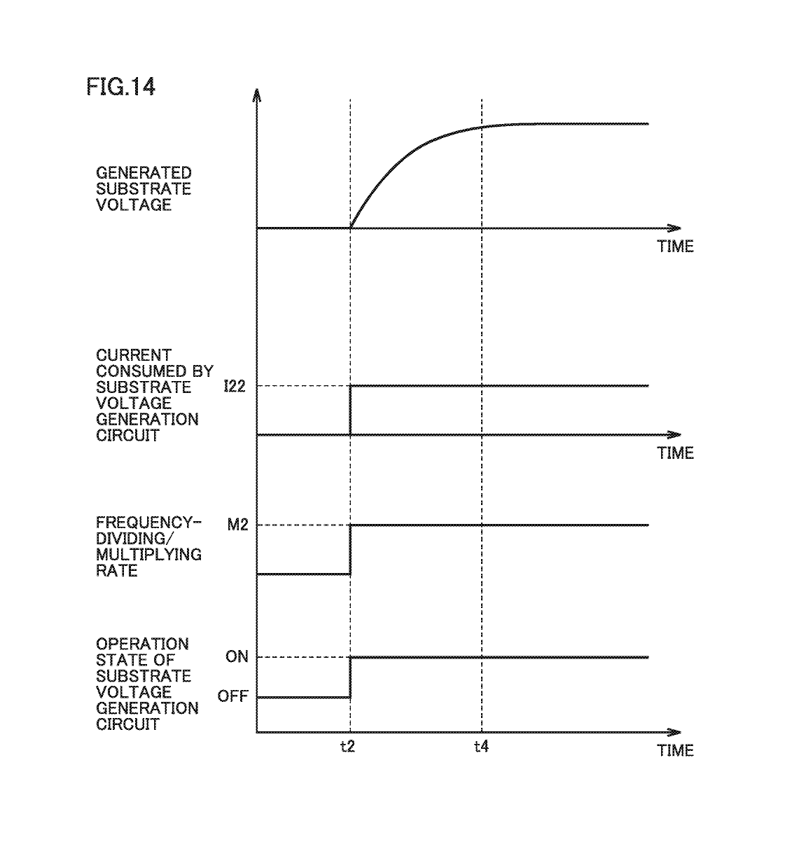

FIG. 14 shows how a generated substrate voltage and a consumed current vary when the frequency-dividing/multiplying rate utilized in the substrate voltage generation circuit is fixed.

With reference to FIG. 9 and FIG. 14, at time t2, CPU 11 sets a frequency-dividing/multiplying rate utilized in frequency-dividing/multiplying circuits 32P and 32N to a value M2 by control signals CNTL2 and CNTL4 and also activates control signal CNTL3 to start substrate voltage generation circuit 30 to operate (or turn it on). Substrate voltage generation circuit 30 generates substrate bias voltages VSUBP and VSUBN, which gradually increase in magnitude and are saturated substantially at a constant value at time t4.

Clock signals PUMPCLKP and PUMPCLKN for charge pump circuits 33P and 33N have a frequency dependent on the frequency-dividing/multiplying rate, and a current consumed by substrate voltage generation circuit 30 depends on a frequency of clock signals PUMPCLKP and PUMPCLKN. Accordingly, when the frequency-dividing/multiplying rate is set to a constant value M2, substrate voltage generation circuit 30 consumes a current of a constant value I22.

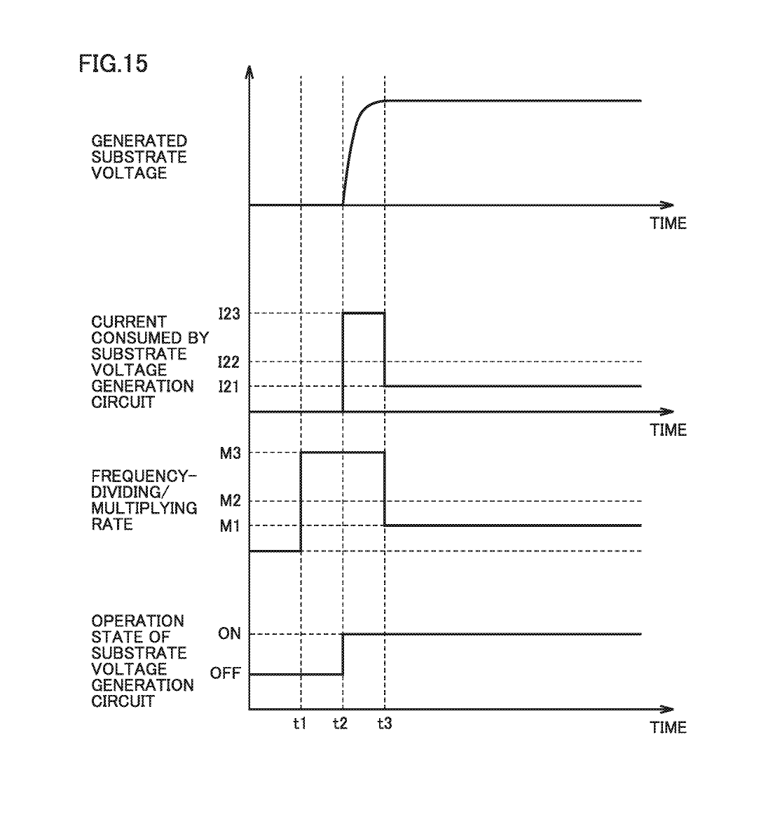

FIG. 15 shows how a generated substrate voltage and a consumed current vary in a case where the frequency-dividing/multiplying rate is temporarily increased when the substrate voltage generation circuit starts to operate. FIG. 15 represents value I22 of a current consumed by substrate voltage generation circuit 30 and value M2 of a frequency-dividing/multiplying rate in the case of FIG. 14 for comparison.

With reference to FIG. 9 and FIG. 15, at time t1, CPU 11 sets a frequency-dividing/multiplying rate utilized in frequency-dividing/multiplying circuits 32P and 32N to a value M3 by control signals CNTL2 and CNTL4. Value M3 of the frequency-dividing/multiplying rate is larger than value M2 of the frequency-dividing/multiplying rate in the case of FIG. 14.

At time t2, CPU 11 activates control signal CNTL3 to start substrate voltage generation circuit 30 to operate (or turn it on). Substrate voltage generation circuit 30 generates substrate bias voltages VSUBP and VSUBN, which rapidly increase in magnitude in comparison with the case of FIG. 14 and are saturated at a substantially constant value around time t3, which is earlier than time t4. Thus, by making a frequency-dividing/multiplying rate large when substrate voltage generation circuit 30 is started, a period of time before substrate bias voltages VSUBP and VSUBN generated are saturated at a constant value can be shortened.

At time t3, by control signals CNTL2 and CNTL4, the set value of the frequency-dividing/multiplying rate utilized in frequency-dividing/multiplying circuits 32P and 32N, i.e., M3, is changed to M1. Value M1 of the frequency-dividing/multiplying rate is larger than value M2 of the frequency-dividing/multiplying rate in the case of FIG. 14. Since substrate bias voltages VSUBP and VSUBN generated have already been saturated at a constant value, a frequency-dividing/multiplying rate can be set as low as possible within a range which can maintain a desired substrate bias voltage.

Thus, according to the semiconductor device of the third embodiment, a frequency-dividing/multiplying rate when substrate voltage generation circuit 30 is started can temporarily be made large to reduce a rising time of substrate voltage generation circuit 30 and also reduce a current subsequently consumed by substrate voltage generation circuit 30.

### Fourth Embodiment

[Configuration of Semiconductor Device]

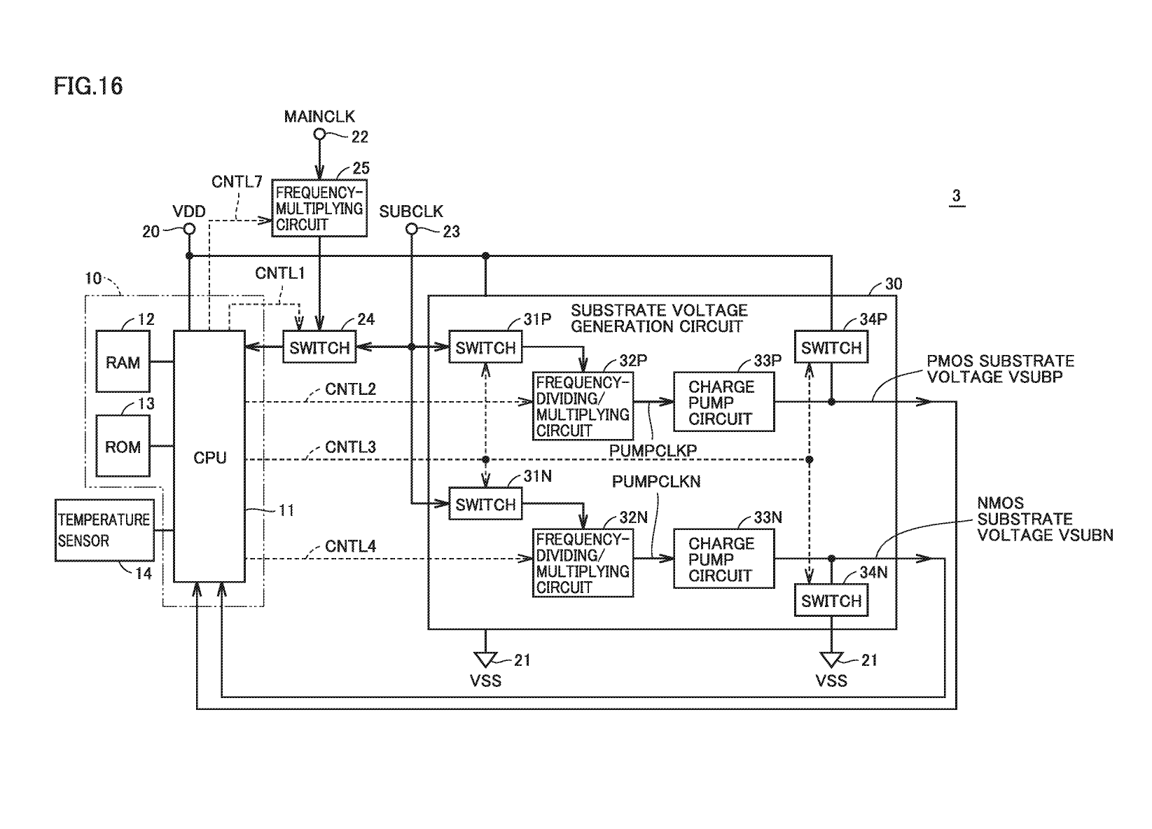

FIG. 16 is a block diagram showing a configuration of a semiconductor device according to a fourth embodiment. FIG. 16 shows a semiconductor device 3, which is different from semiconductor device 2 of FIG. 9 in that the former further comprises a frequency-multiplying circuit 25 for multiplying the frequency of main clock signal MAINCLK. Main clock signal MAINCLK with its frequency multiplied by frequency-multiplying circuit 25 is supplied via switch 24 to CPU 11 and peripheral circuitry of microcomputer 10.

The configuration of frequency-multiplying circuit 25 can be what has been illustrated in FIG. 4, for example. Frequency multiplying circuit 25 operates as controlled by a control signal CNTL7 output from CPU 11. Control signal CNTL7 changes a set value of a frequency-multiplying rate utilized in frequency-multiplying circuit 25, and furthermore, controls frequency-multiplying circuit 25 to start operating and stop operating.

The remainder in FIG. 16 is similar to that of the case of FIG. 9, and accordingly, identical or corresponding components are identically denoted and will not be described repeatedly.

[Procedure to Shift Between Fast Mode of Operation, Slow Mode of Operation and Standby Mode of Operation]

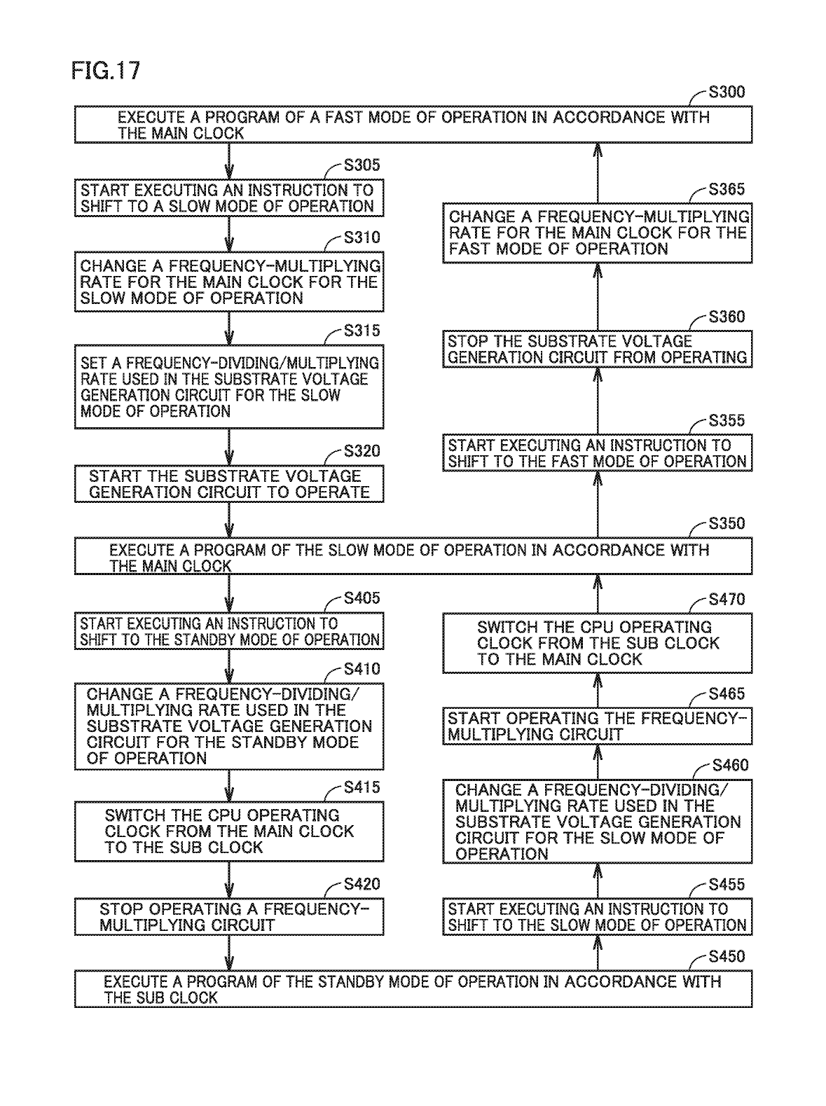

FIG. 17 is a flowchart of a procedure followed to change a mode of operation in the semiconductor device of the fourth embodiment.

In the case of the semiconductor device of the fourth embodiment, CPU 11 has a fast mode of operation, a slow mode of operation and the standby mode of operation. CPU 11 follows a program stored in ROM 13 to operate to switch between these modes of operations. Hereinafter, a procedure to switch the modes of operation will specifically be described.

With reference to FIG. 16 and FIG. 17, initially, CPU 11 follows a program stored in ROM 13 to operate in the fast mode of operation (Step S300) for the sake of illustration. In the fast mode of operation, CPU 11 sets a frequency-multiplying rate utilized in frequency-multiplying circuit 25 to a relatively high value by control signal CNTL7. CPU 11 controls switch 24 by control signal CNTL1 to receive main clock signal MAINCLK having a frequency multiplied by this relatively high frequency-multiplying rate. Furthermore, CPU 11 puts control signal CNTL3 in the inactive state. Thus, substrate voltage generation circuit 30 is stopped from operating.

Subsequently, CPU 11 follows a program to start executing an instruction to shift to the slow mode of operation (step S305). Initially, CPU 11 changes the frequency-multiplying rate utilized in frequency-multiplying circuit 25 to a lower value for the slow mode of operation by control signal CNTL7 (step S310).

Subsequently, CPU 11 sets a frequency-dividing/multiplying rate utilized in frequency-dividing/multiplying circuits 32P and 32N of substrate voltage generation circuit 30 to a value for the slow mode of operation by control signals CNTL2 and CNTL4 (step S315). This value of the frequency-dividing/multiplying rate may be adjusted based on a sensed value of temperature sensor 14.

Subsequently, CPU 11 switches control signal CNTL3 to the active state to start substrate voltage generation circuit 30 to operate (step S320). This completes shifting the fast mode of operation to the slow mode of operation.

In the slow mode of operation, CPU 11 operates in accordance with main clock signal MAINCLK having a frequency multiplied by a relatively low frequency-multiplying rate (step S350). Substrate voltage generation circuit 30 generates substrate bias voltages VSUBP and VSUBN corresponding to the frequency-dividing/multiplying rate set for the slow mode of operation and supplies the same to CPU 11. A reverse substrate voltage in the slow mode of operation has a value lower than that in the standby mode of operation.

A procedure followed to shift from the slow mode of operation to the standby mode of operation with a lower operating frequency will now be described. When CPU 11 follows a program to start executing an instruction to shift to the standby mode of operation (step S405), initially, CPU 11 changes a frequency-dividing/multiplying rate used in substrate voltage generation circuit 30 to a value for the standby mode of operation (step S410). The frequency-dividing/multiplying rate for the standby mode of operation is larger than the frequency-dividing/multiplying rate for the slow mode of operation. Furthermore, this value of the frequency-dividing/multiplying rate may be adjusted based on a sensed value of temperature sensor 14.

Subsequently, CPU 11 switches switch 24 by control signal CNTL1 to receive sub clock signal SUBCLK instead of main clock signal MAINCLK (Step S415). In other words, a clock applied to operate CPU 11 is switched from main clock signal MAINCLK to sub clock signal SUBCLK.

Furthermore, by control signal CNTL7, CPU 11 stops operating frequency-multiplying circuit 25 (step S420). This completes shifting the slow mode of operation to the standby mode of operation. Subsequently, CPU 11 executes a program of the standby mode of operation in accordance with slow sub clock signal SUBCLK (step S450).

A procedure followed to shift from the standby mode of operation to the slow mode of operation will now be described. When CPU 11 follows a program to start executing an instruction to shift to the slow mode of operation (step S455), initially, CPU 11 changes a frequency-dividing/multiplying rate used in substrate voltage generation circuit 30 to a value for the slow mode of operation (step S460). This value of the frequency-dividing/multiplying rate may be adjusted based on a sensed value of temperature sensor 14.

Furthermore, by control signal CNTL7, CPU 11 starts operating frequency-multiplying circuit 25 (step S465). The frequency-multiplying rate utilized in frequency-multiplying circuit 25 is set to a value for the slow mode of operation.

Subsequently, CPU 11 switches switch 24 by control signal CNTL1 to receive main clock signal MAINCLK instead of sub clock signal SUBCLK (Step S470). This completes shifting the standby mode of operation to the slow mode of operation. Subsequently, CPU 11 executes a program of the slow mode of operation in accordance with main clock signal MAINCLK having a frequency multiplied by a relatively low frequency-multiplying rate by frequency-multiplying circuit 25 (step S350).

A procedure followed to shift from the slow mode of operation to the fast mode of operation will now be described. When CPU 11 follows a program to start executing an instruction to shift to the fast mode of operation (step S355), CPU 11 initially switches control signal CNTL3 to the inactive state to stop substrate voltage generation circuit 30 from operating (step S360). This results in applying power supply voltage VDD to a substrate region of a PMOS transistor configuring CPU 11 and applying ground voltage VSS to a substrate region of an NMOS transistor configuring CPU 11.

Subsequently, CPU 11 changes a frequency-multiplying rate utilized in frequency-multiplying circuit 25 to a higher value for the fast mode of operation by control signal CNTL7 (step S365). This completes shifting the slow mode of operation to the fast mode of operation. Subsequently, CPU 11 executes a program of the fast mode of operation in accordance with main clock signal MAINCLK having a frequency multiplied by a relatively high frequency-multiplying rate by frequency-multiplying circuit 25 (step S300).

[Effect]

Hereinafter, a ground for making substrate bias voltages VSUBP and VSUBN different between the fast mode of operation and the slow mode of operation, as described above, will be described.

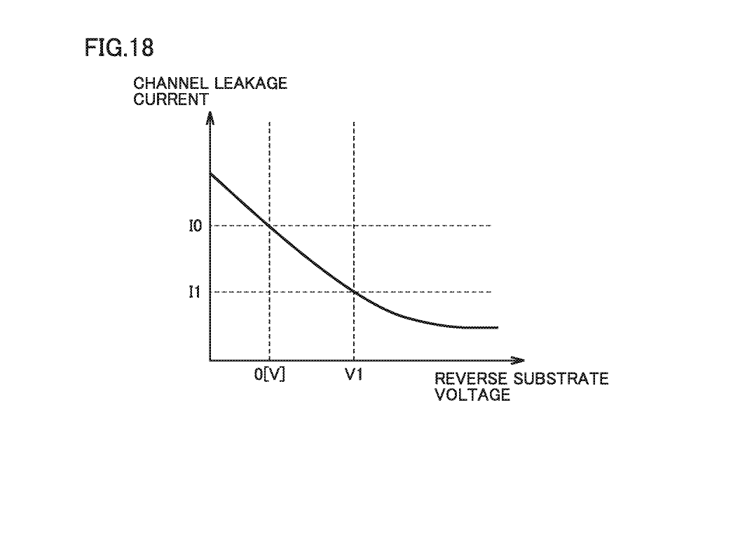

FIG. 18 shows a relationship between a reverse substrate voltage and a channel leakage current. With reference to FIG. 18, when the reverse substrate voltage is increased (i.e., when higher positive substrate bias voltage VSUBP is provided for a PMOS transistor and lower negative substrate bias voltage VSUBN is provided for an NMOS transistor), the transistor's threshold voltage increases. As a result, a channel leakage current of the transistor in the OFF state (also referred to as an off-state leakage current or a subthreshold leakage current) decreases.

Specifically, in the example of FIG. 18, when the reverse substrate voltage is 0 [V] (normally, the PMOS transistor's substrate bias voltage is equal to power supply voltage VDD, and the NMOS transistor's substrate bias voltage is equal to ground voltage VSS), the channel leakage current is I0. In contrast, when the reverse substrate voltage is increased to V1, the channel leakage current decreases from I0 to I1.

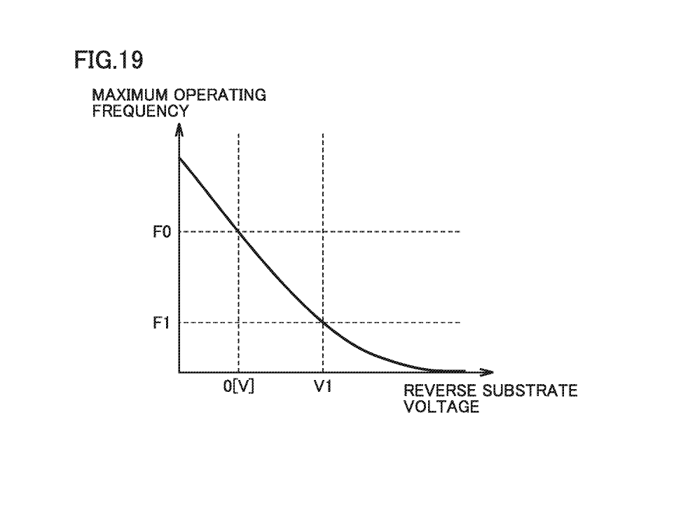

FIG. 19 shows a relationship between a reverse substrate voltage and a maximum operating frequency. With reference to FIG. 19, when the reverse substrate voltage is increased to increase a transistor's threshold voltage, a MOS transistor's ON current decreases. Accordingly, the MOS transistor's maximum operating frequency decreases. Specifically, In the example of FIG. 19, when the reverse substrate voltage is 0 [V], the MOS transistor's maximum operating frequency is F0, whereas when the reverse substrate voltage increases to V1, the maximum operating frequency decreases from F0 to F1.

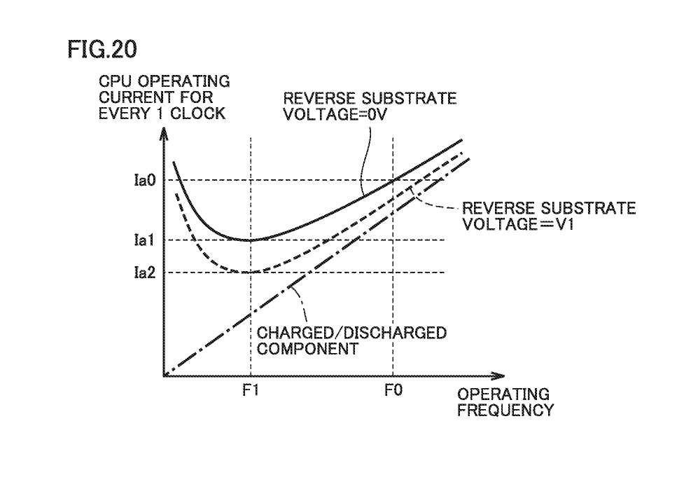

FIG. 20 shows a relationship between a CPU operating frequency and a CPU operating current for every one clock.

With reference to FIG. 20, the CPU's operating current for every one clock is represented by a sum of a channel leakage current of the MOS transistor in the OFF state and a current charged to or discharged from a load capacity of the MOS transistor when the MOS transistor is driven from the ON state to the OFF state or from the OFF state to the ON state. The component of the current charged to or discharged from the load capacity is proportional to the CPU's operating frequency, as shown in FIG. 20 by an alternate long and short dash line. In contrast, regarding the channel leakage current's component, as the operating frequency increases, the charged/discharged current's component has an increased ratio, and accordingly, the channel leakage current's effect decreases. On the contrary, as the operating frequency decreases, the channel leakage current's effect increases. As a result, the CPU operating current for every one clock becomes a downwardly convex curved line, as shown in FIG. 20 (indicated by a solid line for a reverse substrate voltage of 0 V and a broken line for a reverse substrate voltage of V1 (>0). The channel leakage current's component is indicated as a difference between the FIG. 20 downwardly convex curved lines (indicated by the solid and broken lines) and the FIG. 20 charged/discharged current's component (indicated by the alternate long and short dash line). As has been described with reference to FIG. 18, when the reverse substrate voltage is increased from 0 [V] to V1, the channel leakage current's component decreases, and accordingly, the CPU operating current for every one clock decreases.

In the case of the fast mode of operation described with reference to FIG. 17, the reverse substrate voltage is 0 [V]. As has been shown in FIG. 19, since the maximum operating frequency in that case is F0, supposing that the CPU is operated at maximum operating frequency F0, the CPU operating current for every one clock will be T0 as represented in FIG. 20.

In contrast, in the case of the slow mode of operation described with reference to FIG. 17, as compared with the case of the fast mode of operation, the CPU is operated with a lower frequency. If at the time the CPU's operating frequency is set to F1 (Note: operating frequency F1 can be changed by control signal CNTL7) and the reverse substrate voltage is unchanged remaining at 0 [V], then, as shown in FIG. 20, the CPU operating current for every one clock will be Ia1. Here, when the reverse substrate voltage is changed to V1 so that the CPU's maximum operating frequency is F1, the CPU operating current for every one clock decreases to Ia2. This is because the channel leakage current decreases as the reverse substrate voltage increases, as has been described with reference to FIG. 18.

Thus, when the CPU's operating frequency is decreased, the reverse substrate voltage can accordingly be increased (i.e., a frequency-dividing/multiplying rate can be increased) to decrease the CPU's operating current.

### Fifth Embodiment

In order to optimize an operation margin of a SRAM (a Static RAM), an example of applying a substrate bias voltage in accordance with a substrate's temperature will be described.

[Configuration of Semiconductor Device]

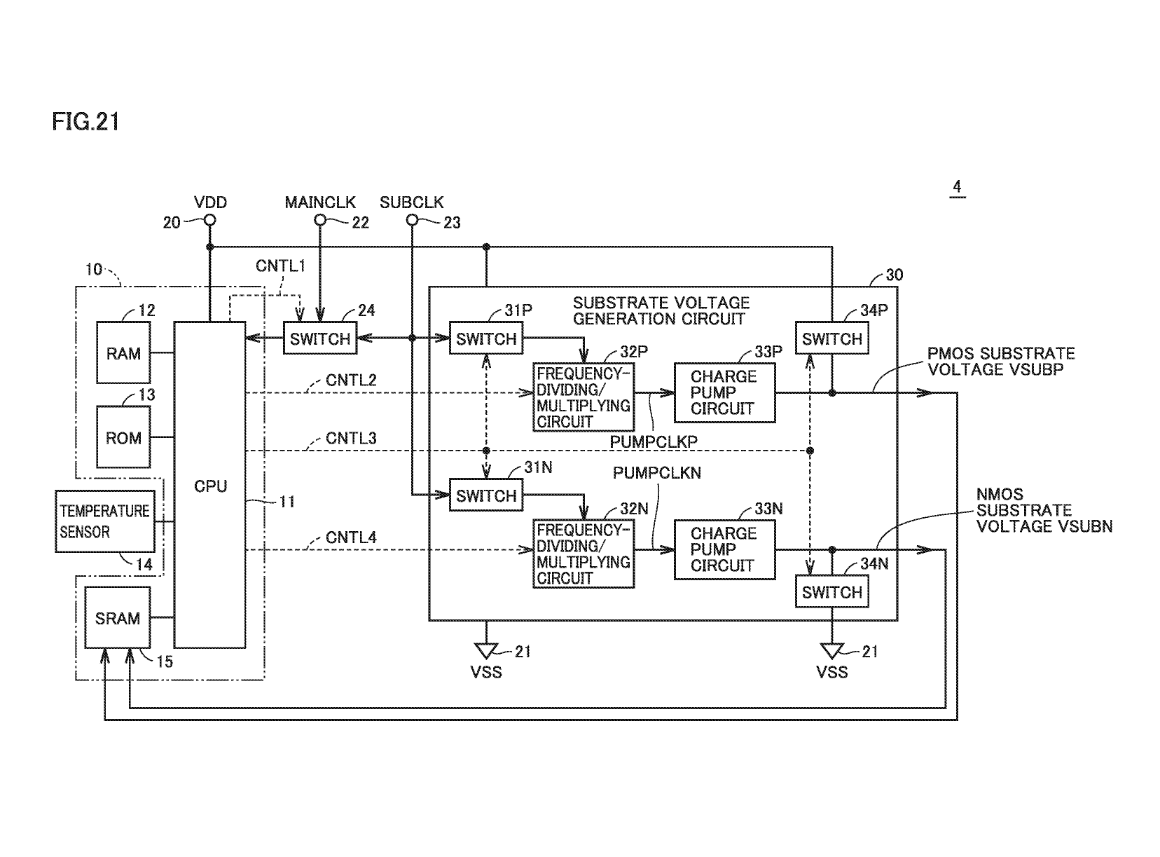

FIG. 21 is a block diagram showing a configuration of a semiconductor device according to a fifth embodiment. FIG. 21 shows a semiconductor device 4, which is different from semiconductor device 2 of FIG. 9 in that the former further comprises a SRAM 15 incorporated in microcomputer 10. Furthermore, semiconductor device 4 of FIG. 21 is different from semiconductor device 2 of FIG. 9 in that substrate bias voltages VSUBP and VSUBN output from the substrate voltage generation circuit are supplied to SRAM 15 rather than CPU 11. The remainder in FIG. 21 is similar to that of FIG. 9, and accordingly, identical or corresponding components are identically denoted and will not be described repeatedly.

Note that it is combinable with the substrate bias control of the CPU described in FIG. 9, FIG. 12, and FIG. 13 or the like. In that case, the semiconductor device is provided with a substrate voltage generation circuit for the CPU apart from a substrate voltage generation circuit for the SRAM.

[Method of Adjusting SRAM's Operation Margin]

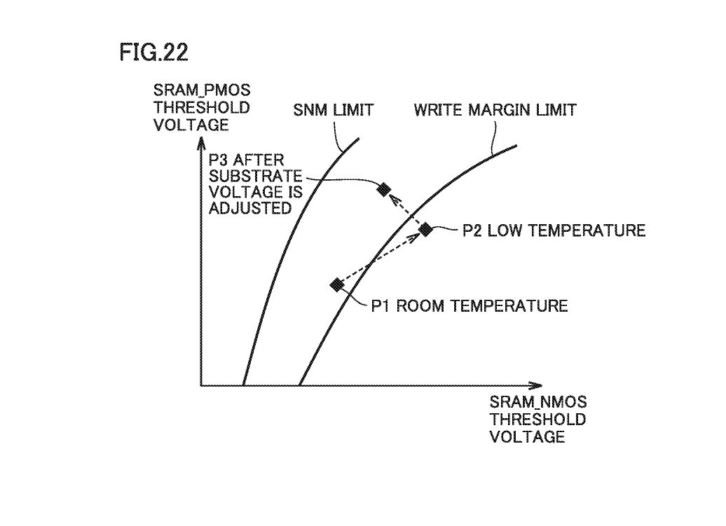

FIG. 22 shows a relationship between a threshold voltage of PMOS and NMOS transistors of a SRAM, and a static noise margin limit and a write margin limit. In FIG. 22, the axis of ordinates represents a threshold voltage of the PMOS transistor configuring the SLAM and the axis of abscissa represents a threshold voltage of the NMOS transistor configuring the SLAM.

When the SRAM has the NMOS transistor with a threshold voltage having a small absolute value and the PMOS transistor with a threshold voltage excessively high, it has a decreased static noise margin (SNM) and can no longer operate. In other words, when a region in FIG. 22 leftwardly of the SNM limit is entered, the SRAM cannot operate. Furthermore, when the NMOS transistor's threshold voltage is high and the PMOS transistor's threshold voltage is excessively low, the SRAM has a decreased write margin and can no longer operate. In other words, the SRAM cannot operate in a region of FIG. 22 rightwardly of the write margin limit. Accordingly, the SRAM must be composed of a MOS transistor having a threshold voltage between the SNM limit and write margin limit of FIG. 22.

The value of the threshold voltage of the MOS transistor composing the SRAM (a relationship between the SNM limit and the write margin limit) varies depending on the transistor's characteristics variation and operating voltage condition. For example, as shown in FIG. 22, it is assumed that at a room temperature the threshold voltage is P1 and the SRAM is operating. When the threshold voltage has increased for low temperature and thus varied to P2, the SRAM no longer operates. In order to avoid such circumstances, a value of a substrate bias voltage supplied to the NMOS and PMOS transistors of the SRAM is adjusted in accordance with a result of sensing a temperature by a temperature sensor. In the example of FIG. 22, substrate bias voltage VSUBP is increased to increase the PMOS transistor's threshold voltage, and substrate bias voltage VSUBN is increased (or has its absolute value decreased) to decrease the NMOS transistor's threshold voltage. This can result in a threshold voltage set to P3 which is the SRAM's operating range.

Thus, according to the present embodiment, adjusting the SRAM's substrate voltage allows the SRAM to have an operation margin with reduced temperature dependency.

<Exemplary Variation>

The first to fifth embodiments can be combined together as desired. Combining all of the embodiments together allows a reduction of a temperature dependency of a standby leak current, a reduction of a rising time of a substrate voltage generation circuit, a reduction of a current consumed by the substrate voltage generation circuit, an optimization of an operating current corresponding to an operating frequency of a CPU, and a reduction of a temperature dependency of an operation margin of a SRAM to be all effectively implemented simultaneously.

While an invention made by the present inventor has specifically been described based on embodiments, the present invention is not limited to the above embodiments and it is needless to say that the present invention can be modified variously within a range which does not depart from its gist.

What is claimed is:

1. A semiconductor device comprising:
a semiconductor integrated circuit including a processing circuit; and
a substrate voltage generation circuit for generating a substrate bias voltage supplied to at least one of transistors configuring the semiconductor integrated circuit,
wherein the substrate voltage generation circuit includes:
a frequency-dividing/multiplying circuit configured to output a frequency-divided/multiplied signal, a frequency of the frequency-divided/multiplied signal being equal to a frequency of a first clock signal divided or multiplied by a frequency-dividing/multiplying rate indicated by the processing circuit; and
a charge pump circuit configured to operate in accordance with the first clock signal divided or multiplied by the frequency-dividing/multiplying circuit, and
wherein a boost voltage output from the charge pump circuit is supplied to the semiconductor integrated circuit as the substrate bias voltage.

2. The semiconductor device according to claim 1, further comprising a temperature sensor for sensing a temperature of a substrate provided with the semiconductor integrated circuit, wherein the processing circuit is configured to adjust the frequency-dividing/multiplying rate based on the temperature sensed by the temperature sensor.

3. The semiconductor device according to claim 2, wherein the processing circuit is configured to make the frequency-dividing/multiplying rate larger as the temperature sensor senses a higher temperature.

4. The semiconductor device according to claim 1, wherein:
the substrate voltage generation circuit is switchable to one of an operating state and a non-operating state in accordance with a command received from the processing circuit;
the charge pump circuit is allowed to operate in the operating state and prevented from operating in the non-operating state;
the substrate bias voltage is supplied to at least one of transistors configuring the processing circuit;
the processing circuit is allowed to operate in accordance with a second clock signal in a first mode of operation and to operate in accordance with a third clock signal in a second mode of operation, the third clock signal having a frequency lower than that of the second clock signal; and
the processing circuit is configured to set the substrate voltage generation circuit to the non-operating state in the first mode of operation and set the substrate voltage generation circuit to the operating state in the second mode of operation.

5. The semiconductor device according to claim 4, further comprising a temperature sensor for sensing a temperature of a substrate provided with the semiconductor integrated circuit, wherein the processing circuit is configured to adjust the frequency-dividing/multiplying rate, based on the temperature sensed by the temperature sensor, in the second mode of operation.

6. The semiconductor device according to claim 4, wherein the processing circuit is configured such that when the processing circuit switches the substrate voltage generation circuit from the non-operating state to the operating state, the processing circuit temporarily makes the frequency-dividing/multiplying rate higher than a prescribed value and subsequently returns the frequency-dividing/multiplying rate to the prescribed value.

7. The semiconductor device according to claim 4, wherein:
the processing circuit is further allowed to operate in accordance with a fourth clock signal in a third mode of operation; the fourth clock signal has a frequency lower than that of the second clock signal and higher than that of the third clock signal; and
the processing circuit is configured to set the substrate voltage generation circuit to the operating state in the third mode of operation and set a frequency-dividing/multiplying rate in the third mode of operation to be lower than a frequency-dividing/multiplying rate in the second mode of operation.

8. The semiconductor device according to claim 7, wherein:
the processing circuit is capable of changing a frequency of the fourth clock signal; and
the processing circuit is configured to set a frequency-dividing/multiplying rate in the third mode of operation, based on the frequency of the fourth clock signal.

9. The semiconductor device according to claim 8, wherein the processing circuit is configured to set a frequency-dividing/multiplying rate in the third mode of operation to a larger value as the fourth clock signal has a lower frequency.

10. The semiconductor device according to claim 7, further comprising a temperature sensor for sensing a temperature of a substrate provided with the semiconductor integrated circuit, wherein the processing circuit is configured to adjust the frequency-dividing/multiplying rate, based on the temperature sensed by the temperature sensor, in the third mode of operation.

11. The semiconductor device according to claim 1, further comprising a temperature sensor for sensing a temperature of a substrate provided with the semiconductor integrated circuit, wherein:
the semiconductor integrated circuit further includes a SRAM (Static Random Access Memory);
the substrate bias voltage is supplied to each transistor configuring the SRAM; and
the processing circuit is configured to adjust the frequency-dividing/multiplying rate based on the temperature sensed by the temperature sensor.

12. The semiconductor device according to claim 11, wherein the processing circuit is configured to adjust the frequency-dividing/multiplying rate such that each transistor configuring the SRAM has a threshold voltage value within a prescribed range.

13. The semiconductor device according to claim 1, wherein each transistor is a MISFET (Metal Insulator Semiconductor Field Effect Transistor) formed on SOTB (Silicon ON Thin Buried oxide).

14. A semiconductor device comprising:
a semiconductor integrated circuit including a processing circuit;
a first substrate voltage generation circuit for generating a first substrate bias voltage supplied to at least one of PMOS (Positive-channel Metal Oxide Semiconductor) transistors configuring the semiconductor integrated circuit; and
a second substrate voltage generation circuit for generating a second substrate bias voltage supplied to at least one of NMOS (Negative-channel Metal Oxide Semiconductor) transistors configuring the semiconductor integrated circuit,
wherein the first substrate voltage generation circuit includes:
a first frequency-dividing/multiplying circuit configured to output a first frequency-divided/multiplied signal, a frequency of the first frequency-divided/multiplied signal being equal to a frequency of a first clock signal divided or multiplied by a first frequency-dividing/multiplying rate indicated by the processing circuit; and
a first charge pump circuit configured to operate in accordance with the first clock signal divided or multiplied by the first frequency-dividing/multiplying circuit,
wherein the second substrate voltage generation circuit includes:
a second frequency-dividing/multiplying circuit configured to output a second frequency-divided/multiplied signal, a frequency of the second frequency-divided/multiplied signal being equal to a frequency of the first clock signal divided or multiplied by a second frequency-dividing/multiplying rate indicated by the processing circuit; and
a second charge pump circuit configured to operate in accordance with the first clock signal divided or multiplied by the second frequency-dividing/multiplying circuit,
wherein a boost voltage output from the first charge pump circuit is supplied to the semiconductor integrated circuit as the first substrate bias voltage, and
wherein a boost voltage output from the second charge pump circuit is supplied to the semiconductor integrated circuit as the second substrate bias voltage.
